(19) United States
(12) Patent Application Publication
(10) Pub. No.: US 2025/0089415 A1
(43) Pub. Date: Mar. 13, 2025

(54) DISPLAY MODULE, LED OPTICAL DEVICE AND MANUFACTURING METHOD THEREFOR

(71) Applicant: Shenzhen Jufei Optoelectronics Co., Ltd., Shenzhen (CN)

(72) Inventors: Wenbo MA, Shenzhen (CN); Ruibing CHEN, Shenzhen (CN); Bin ZHENG, Shenzhen (CN); Meizheng XING, Shenzhen (CN); Zhuangzhi LI, Shenzhen (CN); Xingmin LU, Shenzhen (CN)

(73) Assignee: SHENZHEN JUFEI OPTOELECTRONICS CO., LTD., Shenzhen (CN)

(21) Appl. No.: 18/953,967

(22) Filed: Nov. 20, 2024

Related U.S. Application Data
(63) Continuation-in-part of application No. 18/697,188, filed on Mar. 29, 2024.

(30) Foreign Application Priority Data
Sep. 30, 2021 (CN) 202111166118.8
Sep. 30, 2021 (CN) 202122395097.9
Sep. 30, 2021 (CN) 202122398449.6
Sep. 30, 2021 (CN) 202122409206.8
Oct. 28, 2021 (CN) 202111265275.4
Nov. 5, 2021 (CN) 202111308127.6
Nov. 5, 2021 (CN) 202122699980.7
Nov. 25, 2021 (CN) 202111414585.8
Nov. 30, 2021 (CN) 202111441754.7
Feb. 16, 2022 (CN) 202210141646.6
May 31, 2022 (CN) 202210612146.6
May 31, 2022 (CN) 202210612159.3
Jul. 29, 2022 (CN) 202210909811.8
Nov. 21, 2023 (CN) 202323148601.0
Jul. 29, 2024 (CN) 202411024818.7

(51) Int. Cl. H01L 33/58; H01L 25/075

(52) U.S. Cl. CPC H10H 20/855; H01L 25/0753; H10H 20/0363

(57) ABSTRACT

The invention discloses a display module comprising a black optical layer and a transparent protective layer. The black optical layer covers the light-emitting units and ensures proper alignment and sealing. Light-emitting units penetrate the optical layers to maintain uninterrupted light output. The packaging structure reduces moisture intrusion and protects against environmental damage. A transparent protective layer overlays the black optical layer, enhancing durability and structural integrity. Additionally, the module incorporates an anti-glare film press-fitted onto the packaging layer, minimizing external light interference and optimizing light distribution across viewing angles. These design features enable a thinner display with consistent optical performance.

### CROSS-REFERENCE TO RELATED APPLICATIONS

This application is a continuation-in-part of U.S. application Ser. No. 18/697,188, filed on Mar. 29, 2024, which is the National Stage of International Application No. PCT/CN2022/123579, filed on Sep. 30, 2022, designating the United States, and which claims priority to Chinese Patent Application No. CN202122409206.8U, filed on Sep. 30, 2021. The entire contents of these applications are incorporated herein by reference, Chinese Patent Application No. CN202122398449.6U filed on Sep. 30, 2021, Chinese Patent Application No. CN202122395097.9U filed on Sep. 30, 2021, Chinese Patent Application No. CN202111265275.4A filed on Oct. 28, 2021, Chinese Patent Application No. CN202122699980.7U filed on Nov. 5, 2021, Chinese Patent Application No. CN202111414585.8A filed on Nov. 25, 2021, Chinese Patent Application No. CN202111441754.7A filed on Nov. 30, 2021, Chinese Patent Application No. CN202210141646.6A filed on Feb. 16, 2021, Chinese Patent Application No. CN202210612146.6A filed on May. 31, 2021, Chinese Patent Application No. CN202210612159.3A filed on May. 31, 2021, Chinese Patent Application No. CN202210909811.8A filed on Jul. 29, 2021.This application further claims priority to Chinese Patent Application No. CN202323148601.0U filed on Nov. 21, 2023, Chinese Patent Application No. CN202411024818.7 filed on Jul. 29, 2024.

### BACKGROUND OF THE INVENTION

### Technical Field

The present invention relates to the field of light emitting diode (LED) chip display, and in particular, to a display module, an LED optical device and a manufacturing method therefor.

### Related Art

In the field of LED display technology, Mini COB display modules use a packaging technique where LED chips are directly soldered onto PCB boards. However, due to limitations in the manufacturing process of PCB boards, solder paste may overflow from the solder pads during the soldering process, causing the display screen to appear silver-gray when turned off, which affects the overall black performance. Additionally, during the soldering of LED chips onto the PCB, improper fixation may lead to chip tilt, resulting in uneven surface flatness, which further impacts the uniformity and brightness of the display. In practical applications, improving the visual consistency and display quality of display modules is a key concern. The black performance of the display screen, especially in the off state, is crucial. The choice of materials and the rationality of structural design in the manufacturing process directly affect the final performance of the display module. Therefore, optimizing these aspects to enhance the visual performance of the display is a critical focus in the research and development of this field.

### SUMMARY

The present invention provides a display module and an LED optical device, including a substrate, a plurality of light-emitting units arranged on a top surface of the substrate, and a packaging layer arranged on the substrate and covering each of the light-emitting units, where each of the light-emitting units includes at least one LED chip, the packaging layer is configured to transmit light emitted by the LED chip, and the packaging layer has a thickness greater than a thickness of the light-emitting unit.

Based on the same inventive idea, the present invention further provides a manufacturing method for a display module and an LED optical device, including: providing a substrate; arranging a plurality of light-emitting units on a top surface of the substrate, where each of the light-emitting units includes at least one LED chip; and arranging a packaging layer covering each of the light-emitting units on the substrate, where the packaging layer is configured to transmit light emitted by the LED chip, and the packaging layer has a thickness greater than a thickness of the light-emitting unit.

In the display module, the LED optical device and the manufacturing method therefor provided in the present invention, the display module and the LED optical device each includes a substrate and light-emitting units arranged on a top surface of the substrate, where each light-emitting unit includes at least one LED chip; and further includes a packaging layer arranged on the substrate and covering each light-emitting unit. For the display module, LED lamp beads are no longer used as a light source, but instead LED chips are directly used as a light source. Therefore, use of brackets included in the LED lamp beads can be omitted, which can reduce costs and can also reduce a whole thickness of the display module and the LED optical device, to better facilitate lightening and thinning thereof. In addition, the arranged packaging layer covers each light-emitting unit, which can also satisfy the air-tightness requirement of the display module and the LED optical device and can also protect each light-emitting unit.

The application provides a display module which includes a substrate, on which multiple LED chips are arranged. A lower light-transmitting layer is configured on the substrate, and a black optical layer is arranged on top of the lower light-transmitting layer. Additionally, an upper light-transmitting layer and a transparent protective layer are arranged on the black optical layer. The lower light-transmitting layer at least covers the area between the multiple LED chips on the top surface of the substrate. In the area between the LED chips, the top surface of the lower light-transmitting layer is lower than the top surfaces of the LED chips. The black optical layer 820 covers the top surface of the lower light-transmitting layer, and its top surface is also lower than the top surfaces of the LED chips. The transparent protective layer 900 covers both the top surface of the black optical layer and the top surfaces of the LED chips. The LED chips press against the lower light-transmitting layer and the black optical layer, causing the layers to bend upward around the sides of the LED chips. The LED chips penetrate at least through the black optical layer. The black optical layer does not come into direct contact with the LED chips, as the lower light-transmitting layer acts as a barrier between them.

The application further provides a display module includes a substrate with LED chips arranged on it, and an packaging layer covering both the substrate and the LED chips. The packaging layer fully encloses the LED chips on the substrate. Additionally, the display module includes an AG layer press-fitted onto the packaging layer, with its light-emitting surface exposed and its light-receiving surface directly attached to the packaging layer. In another embodiment, the light-emitting or light-receiving surface of the AG layer can be either a smooth surface or a rough surface. If the light-emitting surface of the AG layer is a rough surface, it contains multiple concave points.

### DESCRIPTION OF THE DRAWINGS

FIG. 1 is the schematic diagram of the display module structure;

FIG. 1-2 is top view of the display module;

FIG. 1-3 is bottom view of the display module;

FIG. 1-4 is cross-sectional view of the display module shown in FIG. 1-2;

FIG. 2-1 is a schematic structural diagram 1 of a display module according to Embodiment 1 of the present invention;

FIG. 2-2 is a schematic structural diagram 2 of a display module according to Embodiment 1 of the present invention;

FIG. 2-3 is a schematic structural diagram 3 of a display module according to Embodiment 1 of the present invention;

FIG. 2-4 is a schematic structural diagram 4 of a display module according to Embodiment 1 of the present invention;

FIG. 2-5a is a schematic structural diagram 5 of a display module according to Embodiment 1 of the present invention;

FIG. 2-5b is a schematic structural diagram 6 of a display module according to Embodiment 1 of the present invention;

FIG. 2-6a is a schematic structural diagram 7 of a display module according to Embodiment 1 of the present invention;

FIG. 2-6b is a schematic structural diagram 8 of a display module according to Embodiment 1 of the present invention;

FIG. 2-7 is a schematic structural diagram 9 of a display module according to Embodiment 1 of the present invention;

FIG. 2-8a is a schematic structural diagram 10 of a display module according to Embodiment 1 of the present invention;

FIG. 2-8b is a schematic structural diagram 11 of a display module according to Embodiment 1 of the present invention;

FIG. 2-9 is a schematic diagram of a display screen according to Embodiment 1 of the present invention;

FIG. 3-1 is a schematic structural diagram 1 of a display module according to Embodiment 2 of the present invention;

FIG. 3-2 is a diagram of an orthographic projection of a display module according to Embodiment 2 of the present invention;

FIG. 3-3 is a schematic structural diagram 2 of a display module according to Embodiment 2 of the present invention;

FIG. 3-4 is a schematic diagram of manufacturing process according to Embodiment 2 of the present invention;

FIG. 3-5 is a schematic diagram of another manufacturing process according to Embodiment 2 of the present invention;

FIG. 4-1 is a schematic structural diagram of a principle of a translucent layer according to Embodiment 9 of the present invention;

FIG. 4-2 is a schematic structural diagram of a reflection layer according to Embodiment 9 of the present invention;

FIG. 4-3 is a schematic structural diagram of a substrate provided with light-emitting units according to Embodiment 9 of the present invention;

FIG. 4-4 is a schematic structural diagram of a third black adhesive layer according to Embodiment 9 of the present invention;

FIG. 4-5 is a schematic diagram 1 of a light path of a translucent layer according to Embodiment 9 of the present invention;

FIG. 4-6 is a schematic diagram 2 of a light path of a translucent layer according to Embodiment 9 of the present invention;

FIG. 4-7 is a schematic structural diagram 1 of a display module according to Embodiment 9 of the present invention;

FIG. 4-8 is a schematic diagram 1 of a light path of the display module in FIG. 4-7;

FIG. 4-9 is a schematic diagram 2 of a light path of the display module in FIG. 4-7;

FIG. 4-10 is a schematic diagram of a plane mirror image according to Embodiment 9 of the present invention;

FIG. 4-11 is a schematic diagram of specular reflection according to Embodiment 9 of the present invention;

FIG. 4-12 is a schematic diagram of diffuse reflection according to Embodiment 9 of the present invention;

FIG. 4-13 is a schematic structural diagram of a display screen according to Embodiment 9 of the present invention;

FIG. 5-1 is a schematic diagram 1 of a display module manufacturing process according to Embodiment 4 of the present invention;

FIG. 5-2 is a schematic diagram 1 of a cross-section after a fourteenth packaging layer is removed from a display module according to Embodiment 4 of the present invention;

FIG. 5-3 is a schematic diagram 2 of a display module manufacturing process according to Embodiment 4 of the present invention;

FIG. 5-4 is a schematic diagram 2 of a cross-section after a fourteenth packaging layer is removed from a display module according to Embodiment 4 of the present invention;

FIG. 5-5 is a schematic cross-sectional view 1 of a display module according to Embodiment 4 of the present invention;

FIG. 5-6 is a schematic cross-sectional view 2 of a display module according to Embodiment 4 of the present invention;

FIG. 5-7 is a schematic cross-sectional view 3 of a display module according to Embodiment 4 of the present invention;

FIG. 5-8 is a schematic cross-sectional view 4 of a display module according to Embodiment 4 of the present invention;

FIG. 5-9 is a schematic cross-sectional view 5 of a display module according to Embodiment 4 of the present invention;

FIG. 5-10 is a schematic cross-sectional view 6 of a display module according to Embodiment 4 of the present invention;

FIG. 5-11 is a schematic cross-sectional view 7 of a display module according to Embodiment 4 of the present invention;

FIG. 5-12 is a schematic cross-sectional view 8 of a display module according to Embodiment 4 of the present invention;

FIG. 5-13 is a schematic cross-sectional view 9 of a display module according to Embodiment 4 of the present invention;

FIG. 6-1 is a cross-sectional schematic diagram of the display module provided by Embodiment 5 of the invention.

FIG. 6-2 is a schematic diagram of a manufacturing method for a display module provided by Embodiment 5 of the invention.

FIG. 6-3 is a cross-sectional schematic diagram of another display module provided by Embodiment 5 of the invention.

FIG. 6-4 is a schematic diagram of another manufacturing method for a display module provided by Embodiment 5 of the invention.

FIG. 6-5 is a cross-sectional schematic diagram of another display module provided by Embodiment 5 of the invention.

FIG. 6-6 is a cross-sectional schematic diagram of another display module provided by Embodiment 5 of the invention.

FIG. 6-7 is a cross-sectional schematic diagram of another display module provided by Embodiment 5 of the invention;

FIG. 6-8 is a cross-sectional schematic diagram of another display module provided by Embodiment 5 of the invention;

FIG. 6-9 is a cross-sectional schematic diagram of another display module provided by Embodiment 5 of the invention;

FIG. 7-1 is a schematic diagram of the display module structure provided by Embodiment 6 of the application.

FIG. 7-2 is a flowchart of the manufacturing process for the display module provided by Embodiment 6 of the application.

FIG. 7-3 is a schematic diagram of the AG functional layer structure formed on the release film provided by Embodiment 6 of the application.

FIG. 7-4 is a schematic diagram of the combination of the AG functional layer and the encapsulation adhesive layer provided by Embodiment 6 of the application.

FIG. 7-5 is a schematic diagram of the surface structure of the AG functional layer provided by Embodiment 6 of the application.

FIG. 7-6 is a schematic diagram of the release film and encapsulation adhesive layer laminated onto the lamp board provided by Embodiment 6 of the application.

FIG. 7-7 is a schematic diagram of another structure where the release film and encapsulation adhesive layer are laminated onto the lamp board, provided by this application;

FIG. 8-1 is a schematic structural diagram 1 of a display module according to Embodiment 9 of the present invention;

FIG. 8-2 is a schematic structural diagram 2 of a display module according to Embodiment 9 of the present invention;

FIG. 8-3 is a schematic structural diagram 3 of a display module according to Embodiment 9 of the present invention;

FIG. 8-4 is a schematic structural diagram 4 of a display module according to Embodiment 9 of the present invention;

FIG. 8-5 is a schematic structural diagram 5 of a display module according to Embodiment 9 of the present invention;

FIG. 8-6 is a schematic structural diagram 6 of a display module according to Embodiment 9 of the present invention.

FIG. 9-1 is a schematic structural diagram of a display module according to Embodiment 8 of the present invention;

FIG. 9-2 is a schematic diagram of a light-emitting unit including four rectangular LED chips according to Embodiment 8 of the present invention;

FIG. 9-3 is a schematic diagram of an arrangement of LED chips in a spliced substrate according to Embodiment 8 of the present invention;

FIG. 9-4 is a schematic diagram of another arrangement of LED chips in a spliced substrate according to Embodiment 8 of the present invention;

FIG. 9-5 is a schematic diagram of a light-emitting unit including three elliptical LED chips according to Embodiment 8 of the present invention;

FIG. 9-6 is a schematic diagram of electrically connecting sub-central electrodes of LED chips according to Embodiment 8 of the present invention;

FIG. 9-7 is a schematic diagram of electrode orientations of LED chips in another light-emitting unit according to Embodiment 8 of the present invention;

FIG. 9-8 is a schematic diagram of electrode orientations of LED chips in still another light-emitting unit according to Embodiment 8 of the present invention;

FIG. 9-9 is another schematic structural diagram of a display module according to Embodiment 8 of the present invention;

FIG. 9-10 is a schematic diagram of an adjustable distance and an adjustable angle of an LED chip relative to a rotational symmetry center according to Embodiment 8 of the present invention;

FIG. 9-11 is a schematic diagram of a first light-emitting unit including three LED chips according to Embodiment 8 of the present invention;

FIG. 9-12 is a schematic diagram of a second light-emitting unit including three LED chips according to Embodiment 8 of the present invention;

FIG. 9-13 is a schematic diagram of a third light-emitting unit including three LED chips according to Embodiment 8 of the present invention;

FIG. 9-14 is a schematic diagram of a fourth light-emitting unit including three LED chips according to Embodiment 8 of the present invention;

FIG. 9-15 is a schematic diagram of a fifth light-emitting unit including three LED chips according to Embodiment 8 of the present invention;

FIG. 9-16 is a schematic diagram of a first light-emitting unit including four LED chips according to Embodiment 8 of the present invention;

FIG. 9-17 is a schematic diagram of a second light-emitting unit including four LED chips according to Embodiment 8 of the present invention;

FIG. 9-18 is a schematic diagram of a third light-emitting unit including four LED chips according to Embodiment 8 of the present invention;

FIG. 9-19 is a schematic diagram of a fourth light-emitting unit including four LED chips according to Embodiment 8 of the present invention;

### DETAILED DESCRIPTION

For ease of understanding the present invention, the present invention is described more comprehensively below with reference to the accompanying drawings. The accompanying drawings show exemplary embodiments of the present invention. However, the present invention may be implemented in many different forms, and is not limited to the embodiments described in this specification. On the contrary, the embodiments are provided to make understanding of the disclosed content of the present invention more comprehensive.

Unless otherwise defined, meanings of all technical and scientific terms used in this specification are the same as those usually understood by a person skilled in the art to which the present invention belongs. In the present invention, terms used in the specification of the present invention are merely intended to describe objectives of the specific embodiments, but are not intended to limit the present invention.

It should be noted that in this specification, claims, and accompanying drawings of the present invention, the terms “first”, “second”, and so on are intended to distinguish similar objects but do not necessarily indicate a specific order or sequence. It should be understood that such data used in this way can replace each other in an appropriate situation for describing the embodiments of the present invention herein. In addition, terms “include” and “have” and any of their variations are intended to cover nonexclusive inclusion, for example, a process, method, system, product, or device that includes a series of steps or units does not have to be limited to those clearly listed steps or units, but may include another step or unit that is not clearly listed or is inherent to the process, method, product, or device.

In the present invention, orientation or position relationships indicated by the terms such as “upper”, “lower”, “inner”, “middle”, “outer”, “front”, and “back” are based on orientation or position relationships shown in the accompanying drawings. The terms are used mainly for better describing the present invention and the embodiments thereof, rather than indicating that the mentioned apparatus, element, or component needs to have a particular orientation or needs to be constructed and operated in a particular orientation. In addition, some of the foregoing terms may be further used for representing other meanings in addition to an orientation or a position relationship. For example, the term “upper” may alternatively be used for representing an attachment relationship or a connection relationship in some cases. A person of ordinary skill in the art may understand the specific meanings of the terms in the present invention according to specific situations. In addition, terms such as “arrangement”, “connection”, and “fixation” shall be understood in a broad sense. For example, “connection” may be a fixed connection, a detachable connection, or an integral connection; may be a mechanical connection or an electrical connection; or may be a direct connection, an indirect connection by using an intermediate medium, or internal communication between two apparatuses, elements, or components. A person of ordinary skill in the art may understand the specific meanings of the foregoing terms in the present invention according to specific situations.

It should be noted that the embodiments in the present invention and features in the embodiments may be mutually combined in case that no conflict occurs. The present invention is described in detail in the following with reference to the accompanying drawings by using embodiments.

The present invention provides a display module and an LED device, applicable to various fields such as household display, medical display, decoration display, transportation display, and advertisement display. For example, the display module is specifically applicable to various electronic devices, including but not limited to, a monitor, a mobile terminal, a computer, a wearable device, an advertisement device, and an in-vehicle device.

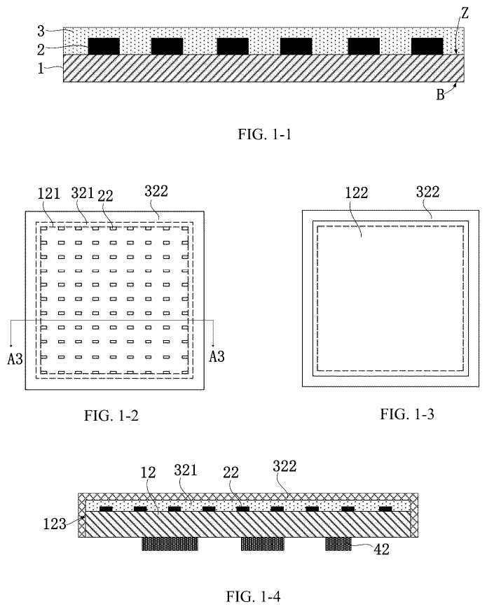

This application provides a display module and an LED device, which can be applied to various fields such as household display, medical display, decorative display, transportation display, and advertising display. For example, it can be specifically applied to various electronic devices, including but not limited to monitors, mobile terminals, computers, wearable devices, advertising equipment, and in-vehicle devices. As shown in FIG. 1, the display module includes a substrate 1, several light-emitting units 2, and a packaging layer 3. In this application, the substrate 1 can function as the display backplane of the display module or serve as an independent supporting substrate for carrying the light-emitting units. The substrate 1 may be a single-layer substrate or a composite substrate comprising at least two layers. It can be a flexible substrate or a rigid substrate, with no limitation imposed in this embodiment. As shown in FIG. 1, the surface labeled Z represents the top side of the substrate, and the surface labeled B represents the back side, with the side surfaces located between the front and back sides.

The light-emitting units 2 are arranged on the top surface of the substrate, one light-emitting unit 2 may include only one LED chip or two or more LED chips, and at least one of quantities of LED chips included in the light-emitting units 2 and light emission colors may be the same. Alternatively, at least one of quantities of LED chips included in some light-emitting units 2 and light emission colors may be different. The LED chips in the present invention may be micron-sized LED chips (for example, Mini LED chips or Micro LED chips), and may be, for example, micron-sized flip LED chips. Certainly, all or some of the LED chips may alternatively be replaced with micron-sized face-up or vertical LED chips, and certainly may alternatively be replaced with ordinary-sized LED chips according to a size requirement.

In all embodiments of this application, the light-emitting unit or light-emitting element may be a flip-chip, and more specifically, a micro flip-chip LED. The light-emitting unit or element 2 can be a flip-chip, which is fixed and electrically connected to the substrate 1 through solder pads. The solder pads on the substrate I are generally arranged in an array, with the pad layout customized according to the positioning requirements of the flip-chip LED 2 being installed. The solder pads can be created by forming a conductive layer on the surface of the substrate's insulating base layer and then using etching or similar processing methods to remove portions of the metal, exposing the insulating layer to form the desired solder pad areas and corresponding circuit pathways in the circuit layer. Subsequently, the flip-chip LED is positioned on the substrate using a die bonding process, thereby achieving both fixed attachment and electrical connection between the flip-chip LED and the substrate.

The packaging layer 3 is arranged on the substrate 1, covering each light-emitting unit 2, and it allows the light emitted by the LED chips of the light-emitting units 2 to pass through. The thickness of the packaging layer 3 is greater than the thickness of the light-emitting units 2. The packaging layer 3 may be arranged only on the top surface of the substrate, fully covering the top surface, or partially covering only a portion of it. The packaging layer 3 may also extend from the top surface of the substrate to at least one side surface, and even to the back surface of the substrate. Additionally, the packaging layer 3 can be a single-layer structure or a multi-layer structure composed of at least two layers. It is evident that the display module structure provided in this application provides great flexibility and is suitable for a wide range of scenarios. It also achieves a thinner overall profile and lower cost while meeting airtightness requirements. To facilitate understanding, the following embodiments provide examples illustrating specific structural variations and manufacturing methods.

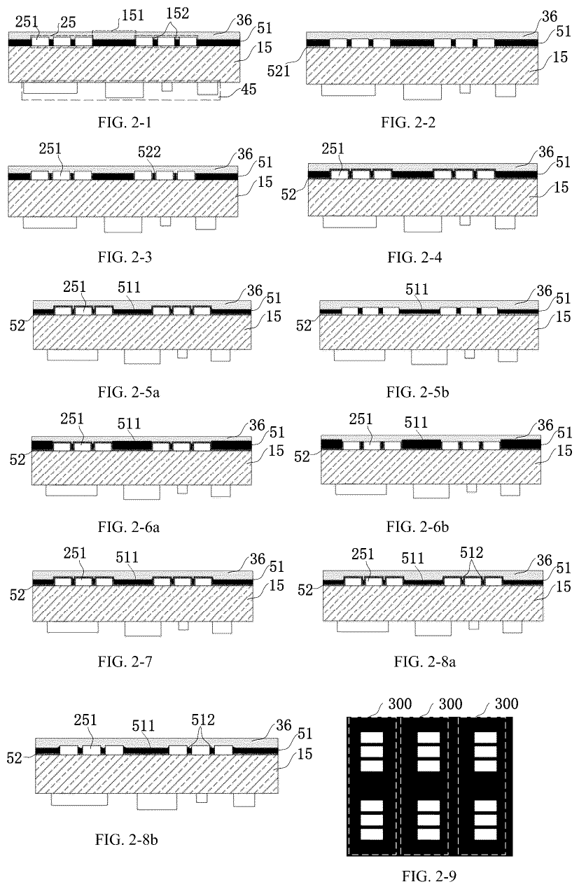

An example of the display module provided in this embodiment is shown in FIGS. 1-2 and 1-3, where FIG. 1-2 is a top view of the display module (processed with perspective for better understanding), and FIG. 1-3 is a bottom view of the display module. FIG. 1-4 is a cross-sectional view along A3-A3 in FIG. 1-3. As shown, the display module in this example includes a substrate 12 and several light-emitting units 22. All light-emitting units 22 are installed within the display region 121 located on the top surface of the substrate. In this embodiment, the display region 121 on the top surface of the substrate is an area configured for the electrical connection of the light-emitting units 22 to drive and control their illumination for display purposes. Additionally, this region serves as a support area for the light-emitting units 22. The number of LED chips included in the light-emitting units 22, their emission colors, sizes, and types, as well as the material, shape, and dimensions of the substrate 12, can refer to but are not limited to the previous embodiments, which will not be repeated here.

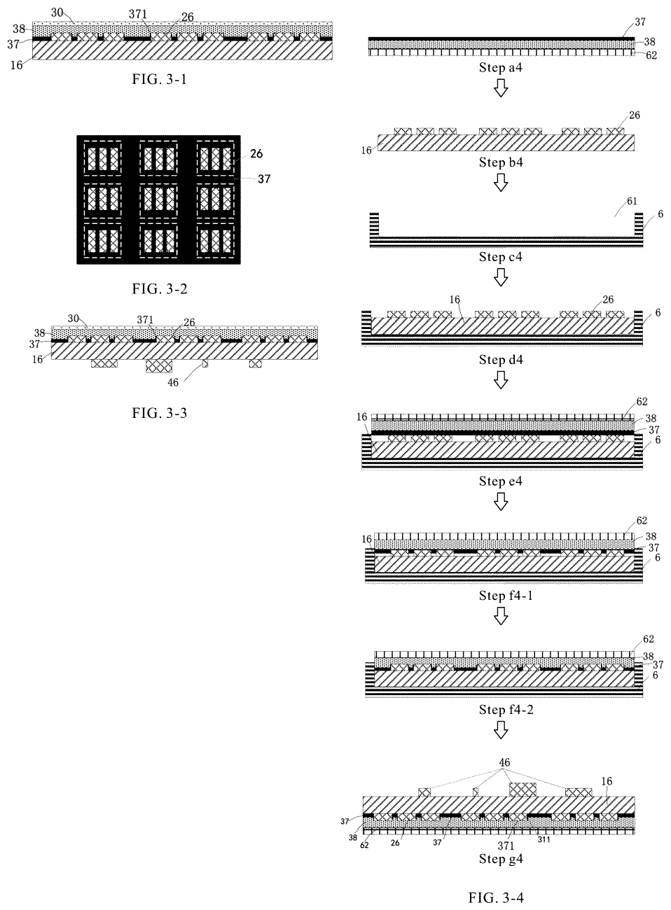

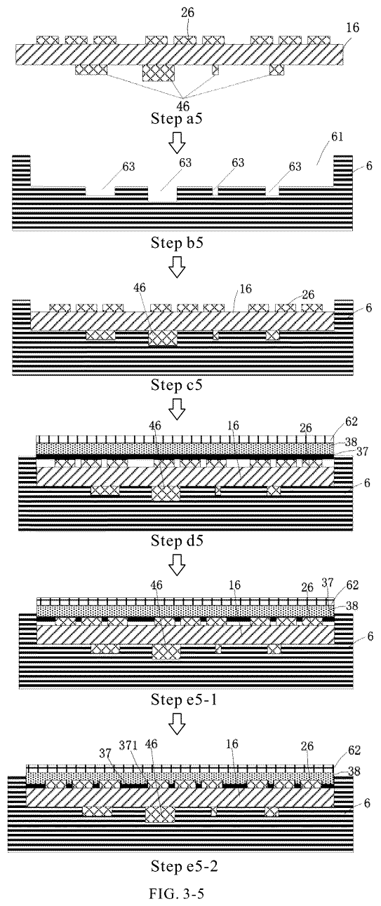

The back surface of the substrate 12 is provided with a circuit function region 122, where a driving electronic component 42 is installed to drive and control the light-emitting units 22. On the display region 121 located on the top surface of the substrate, a packaging layer covers all the light-emitting units 22. This packaging layer includes a first packaging layer 321 that covers the top surface of the substrate, and a second packaging layer 322. The second packaging layer 322 covers the first packaging layer 321 and extends to the back surface of the substrate 12, covering at least a portion of the side surface 123 of the substrate 12. This configuration covers the joint between the first packaging layer 321 and the substrate 12, as shown in FIG. 3-3, thus preventing moisture from directly entering the display module through the joint between the first packaging layer 321 and the substrate 12. Furthermore, in environments where moisture is present, the moisture must pass through the bonding area between the second packaging layer 322 and the side surface 123 of the substrate 12 before reaching the joint between the first packaging layer 321 and the substrate 12. This effectively extends the path for moisture intrusion into the display module, providing better protection for the light-emitting units 22 and further enhancing the reliability of the display module. It should be understood that the specific area of the side surface 123 of the substrate 12 covered by the second packaging layer 322 can be flexibly set according to application requirements. For example, the second packaging layer 322 may only cover a portion of the side surface 123, or it may cover the entire side surface to further extend the path of moisture intrusion and improve the reliability of the display module.

It should be understood that, in this embodiment, the specific formation methods of the first packaging layer 321 and the second packaging layer 322 can include, but are not limited to, molding, printing, or potting, without limitation to these methods. Both the first packaging layer 321 and the second packaging layer 322 are light-transmitting layers, and their materials can either be the same (for example, both can be transparent packaging layers) or different. Additionally, both the first packaging layer 321 and the second packaging layer 322 can be single-layer structures, or at least one of them can be configured as a composite-layer structure composed of at least two sub-layers.

In some examples of this embodiment, at least one of the first packaging layer 321 or the second packaging layer 322 can include at least one of light conversion particles and diffusion particles according to the requirements. For example, in one application scenario, the first packaging layer 321 contains light conversion particles to achieve light color conversion, while the second packaging layer 322 contains diffusion particles to further enhance light extraction efficiency.

### Embodiment 1

This embodiment provides a display module that can enhance the contrast and brightness of the entire screen. The display module provided in this embodiment can be implemented independently of other embodiments. An example of the display module in this embodiment is shown in FIG. 2-1. It includes a substrate 15 with several light-emitting units 25 arranged on the top surface of the substrate. Each light-emitting unit 25 consists of multiple LED chips 251. A black optical layer 51 covers the top surface of the substrate. It covers the first region 151 located between the light-emitting units 25 and the second region 152 located between the LED chips 251 within each light-emitting unit 25. The light-emitting surfaces of the LED chips 251 are exposed through the black optical layer 51, and the height of the black optical layer 51 is less than the height of the LED chips 251. A first packaging layer 36 is arranged on the top surface of the substrate, covering both the black optical layer 51 and the light-emitting units 25.

As shown in FIG. 2-1, electronic components 45 are arranged on the back surface of the substrate to drive the LED chips 251 to emit light. It is understood that, in practical applications, the LED chips 251 can be mounted on the top surface of the substrate either by soldering or by surface mounting, without limitation to a specific method in this invention. The first packaging layer 36 can be formed on the substrate by methods including, but not limited to, injection molding, dispensing, or molding, ensuring a tight bond between it and the black optical layer 51 as well as the light-emitting units 25. In some examples, the first packaging layer 36 can cover only the light-emitting units 25 on the top surface of the substrate, or it can also cover the entire top surface of the substrate. It should be noted that the first packaging layer 36 can include, but is not limited to, a certain proportion of diffusion particles to enhance light extraction. For example, it may contain a specific amount of diffusion powder or phosphor powder. In the embodiment, the display module also includes a moisture-proof layer. The moisture-proof layer includes a first moisture-proof layer positioned between the black optical layer and the top surface of the substrate, and a second moisture-proof layer covering the LED chips.

As shown in FIG. 2-2, it is a schematic cross-sectional view of the moisture-proof layer structure of a display module and LED optical device. In FIG. 2-2, the first moisture-proof layer 521 is arranged between the black optical layer 51 and the top surface of the substrate. As shown in FIG. 2-3, it depicts another schematic cross-sectional view of the moisture-proof layer structure of a display module and LED optical device. In FIG. 2-3, the second moisture-proof layer 522 covers the LED chips 251.

The moisture-proof layer 52 can be formed by methods including, but not limited to, molding or hot pressing. Additionally, the moisture-proof layer 52 can be arranged both between the black optical layer and the top surface of the substrate, as well as covering the LED chips. For example, as shown in FIG. 2-4, it illustrates another schematic cross-sectional view of the moisture-proof layer structure of a display module and LED optical device. In FIG. 2-4, the moisture-proof layer 52 is simultaneously arranged between the black optical layer and the top surface of the substrate and also covers the LED chips 251. The side surface of each LED chip 251 refers to the surface located between its light-emitting surface and its bottom surface.

In some examples, as shown in FIGS. 2-4, the moisture-proof layer 52 includes a first moisture-proof layer 521 and a second moisture-proof layer 522. The first moisture-proof layer 521 and the second moisture-proof layer 522 can be integrally formed or non-integrally formed. It should be noted that when the first moisture-proof layer 521 and the second moisture-proof layer 522 are non-integrally formed, their junction should be tightly connected during installation to prevent moisture from entering. It is worth mentioning that the moisture-proof layer 52 may include, but is not limited to, a polymer nanolayer. This layer can completely block the penetration of water molecules and can also bond well with wafers, PCBs, and packaging resin, enhancing mechanical strength. At the same time, it does not affect the display performance, improving user satisfaction.

In some examples, as shown in FIG. 2-8a, the top surface of the black optical layer 511 located in the first region 151 is parallel to both the top side of the substrate and the top surface of the black optical layer 512 in the second region 152.

In the example of the display module shown in FIG. 2-8b, the top surface of the black optical layer 511 in the first region 151, near the area of the light-emitting unit 25, can also be inclined or curved. The maximum height of the top surface of the black optical layer 511 is lower than the height of the LED chip's 251 light-emitting surface, increasing the coverage area on the side of the LED chip 251. This design significantly reduces light leakage between light-emitting units. Additionally, in another display module example, as shown in FIGS. 2-6a and 2-6b, the height of the top surface of the black optical layer 511 is greater than the height of the LED chip's 251 light-emitting surface, preventing light leakage between light-emitting units and improving display performance. By setting the height of the black optical layer between the light-emitting units higher than the LED chip's light-emitting surface, it ensures that each light-emitting unit does not interfere with others during light mixing, resulting in better display quality. Furthermore, as shown in FIG. 2-7, another display module design is illustrated. In this design, the top surface of the black optical layer 511 may be a concave curve toward the top side of the substrate. The maximum height of the top surface of the black optical layer 511 is the same as the height of the light-emitting surface of LED chip. That is, the black optical layer can extend along the side of the LED chip toward its light-emitting surface and eventually align flush with it.

In some embodiments, as shown in FIGS. 2-8a and 2-8b, the top surface 512 of the black optical layer 51 in the second region 152 can also be a concave curve toward the top side of the substrate. It should be noted that the top surface of the black optical layer 512 in the second region does not exceed the height of the light-emitting surface of LED chip. Since the second region is located between the LED chips within the light-emitting unit 25, if the height of the top surface of black optical layer in the second region were to exceed the height of the light-emitting surface of LED chip, it would significantly impact the light-mixing effect of the LED chips, potentially preventing effective light mixing. To enhance the light-mixing effect and display performance, the top surface of the black optical layer in the second region should not exceed the height of the light-emitting surface of LED chip.

It should be noted that in this embodiment, the top surface of the black optical layer in the first region and the top surface of the black optical layer in the second region may be both parallel to the top surface of the substrate, and may alternatively be both curved surfaces or inclined surfaces concave toward the top surface of the substrate; or the top surface of the black optical layer in the first region is parallel to the top surface of the substrate, and the top surface of the black optical layer in the second region is a curved surface or an inclined surface concave toward the top surface of the substrate; or the top surface of the black optical layer in the first region is a curved surface or an inclined surface concave toward the top surface of the substrate, and the top surface of the black optical layer in the second region is parallel to the top surface of the substrate; or certainly the top surfaces of the black optical layers in the first region and the second region may be parallel to the top surface of the substrate in parts of the regions and be curved surfaces or inclined surfaces concave toward the top surface of the substrate in other parts of the regions, which may be set by a person skilled in the art according to an actual case and a requirement and is not limited herein.

It should be noted that one display module in this embodiment may include, but not limited to, a case that the height of the top surface of the black optical layer in the first region is greater than the height of the top out-light surface of the LED chip and the height of the top surface of the black optical layer in the second region is less than the height of the top out-light surface of the LED chip; may alternatively include a case that the height of the top surface of the black optical layer in the first region is less than the height of the top out-light surface of the LED chip and the height of the top surface of the black optical layer in the second region is less than the height of the top out-light surface of the LED chip; and certainly may alternatively be a case that the height of the top surface of the black optical layer in the first region is equal to the height of the top out-light surface of the LED chip and the height of the top surface of the black optical layer in the second region is equal to the height of the top out-light surface of the LED chip. A person skilled in the art may set the heights of the top surfaces of the black optical layers in the first region and the second region according to an actual case and a requirement, as long as the height of the top surface of the black optical layer in the second region is not greater than the height of the top out-light surface of the LED chip, which is not limited in this embodiment. Preferably, in this embodiment, the height of the top surface of the black optical layer in the first region is greater than the height of the top out-light surface of the LED chip, to prevent crosstalk between light-emitting units. It should be noted that a case that the top surface of the black optical layer is higher than the top out-light surface of the LED chip refers to a case that at least one part of the top surface of the black optical layer is higher than the top out-light surface of the LED chip; and a case that the top surface of the black optical layer is not higher than the top out-light surface of the LED chip refers to a case that no part of the top surface of the black optical layer is higher than the top out-light surface of the LED chip, but may include a case that at least one part thereof is flush with the top out-light surface of the LED chip. It should be noted that whether the black optical layers in the first region and the second region are parallel to the top surface of the substrate or concave toward the top surface of the substrate, and the heights of the black optical layers in the first region and the second region may be combined in a plurality of manners, which may be set by a person skilled in the art according to an actual case and a requirement.

For the quantity, light emission colors, sizes, and the like of LED chips included in the light-emitting units 25 in this embodiment, reference may be made to, but not limited to, the arrangement of light-emitting units in other embodiments. Details are not described herein again.

In some implementations, the black optical layer 51 is a mold-pressed black optical layer mold-pressed on the top surface of the substrate or a hot-pressed black optical layer hot-pressed on the top surface of the substrate. In some examples, if the black optical layer 51 is a mold-pressed black optical layer mold-pressed on the top surface of the substrate, a substrate made of a PCB material may be selected, cleaned, and dehumidified, then LED chips are fixed on a top surface of the substrate of the PCB, and an electronic element is mounted on a back surface of the PCB, to ensure that all the LED chips can be normally illuminated after a period of time of aging verification. Then, the black optical layer is mold-pressed to cover surfaces of the LED chips, baked, and cured, and then the black adhesive on the surfaces is etched through, including but not limited to, chemical etching or physical etching, until the surfaces of the chips are completely bared. Finally, a packaging layer is mold-pressed on the mold-pressed black optical layer and the surfaces of the LED chips, to improve reliability of a product and achieve a light mixing effect. In some examples, if the black optical layer 51 is a hot-pressed black optical layer hot-pressed on the top surface of the substrate, a pre-manufactured hot-pressed black adhesive film sheet may be hot-pressed onto the substrate and surfaces of LED chips, baked, and cured, and the hot-pressed black adhesive film sheet is hot-pressed and then formed into a shape of being concave toward the top surface of the substrate together with the peripheries of the LED chips. Then, the hot-pressed black adhesive film sheet on the surfaces of the LED chips is etched in a manner including, but not limited to, chemical etching or physical etching, until the surfaces of the LED chips are completely bared, to ensure that light is out from top light-emitting surfaces of the LED chips normally. Finally, a packaging layer is mold-pressed on the hot-pressed black adhesive film sheet and the surfaces of the LED chips, to improve reliability of a product and achieve a light mixing effect.

In this embodiment, black optical layers with different heights and different shapes are arranged between light-emitting units on the top surface of the substrate and between LED chips in a light-emitting unit, to improve its contrast and luminance, improve its display effect, and moisture-proof layers are arranged between the black optical layer and the top surface of the substrate and on surfaces of the LED chips, to prevent intrusion of moisture, resolve problems of the display module of poor ink color consistency, poor contrast, and failure caused by humidification, improve the contrast and the display effect, and greatly improve use satisfaction of the user.

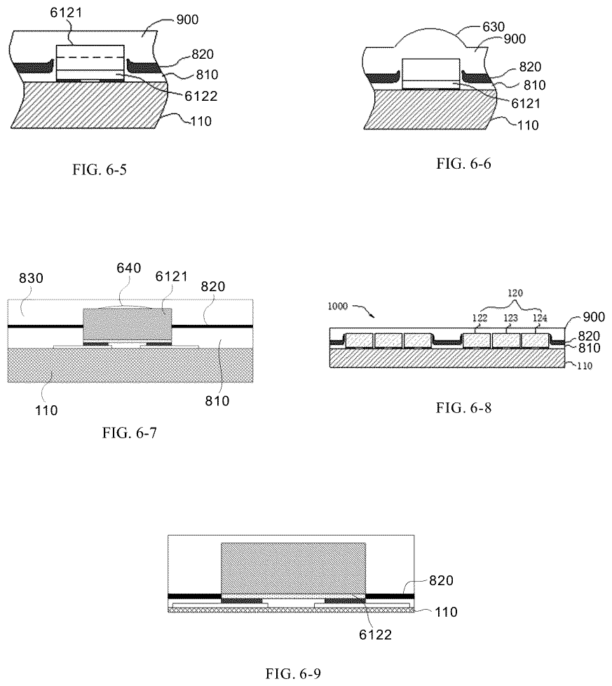

This embodiment further provides a display screen, as shown in FIG. 6-9. To more clearly indicate the structure of the display screen, a packaging layer is subject to perspective treatment in the drawing. The display screen includes at least one display module shown in the foregoing examples. For example, as shown in FIG. 6-9, three display modules 300 are spliced to form the display screen, and two adjacent display modules are fixed through, including but not limited to, a fixation bracket, a screw, or glue. It should be noted that the display screen may be set as a plane, and may alternatively be set as a curved surface. A specific setting manner may be set by a person skilled in the art according to an actual case and a requirement and is not limited in the present invention.

In this example, as shown in FIG. 2-9, three display modules 300 are assembled together. Adjacent display modules are fixed using, but not limited to, mounting brackets, screws, or adhesives. It should be noted that the display screen can be configured as either a flat surface or a curved surface. The specific configuration can be determined by those skilled in the art based on actual conditions and requirements, without limitation by this application.

### Embodiment 2

This embodiment provides an exemplary display module, as shown in FIGS. 3-1 to 3-2. It includes a substrate 16 with light-emitting units installed on it, each light-emitting unit comprising at least one LED chip 26. The packaging layer of the display module consists of a black optical layer 37, a first packaging layer 38, and a second packaging layer 30. Optionally, in this embodiment, the display module may also include a transparent protective layer 62 covering the first packaging layer 38, which is referred to as the first carrier film in some embodiments. The inclusion of the transparent protective layer 62 can further enhance the protective performance of the display module. Additionally, the thickness of the transparent protective layer in this embodiment can be flexibly adjusted according to requirements, for example, ranging from, but not limited to, 10 μm to 300 μm. It should be understood that, in this example, the transparent protective layer 62 can have a composite layer structure made up of at least two sub-layers or a single-layer structure. The transparent protective layer 62 may be, but is not limited to, a transparent layer or a plastic sheet.

For ease of understanding, a manufacturing method for a display module is exemplified below in this embodiment, and includes, but not limited to:
Step a3: manufacture a substrate and a packaging layer.

In this embodiment, the manufacturing a substrate includes: arranging the substrate 16, and arranging LED chips on a top surface of the substrate 16. In some examples, an electronic element may be further arranged on a back surface of the substrate 16, that is, an electronic element is arranged on a back surface of the substrate 16 first before a surface of the packaging layer provided with the black optical layer 37 is press-fit to the top surface of the substrate 16. Certainly, in some other examples, an electronic element may alternatively be arranged on the back surface of the substrate 16 after the packaging layer is formed on the top surface of the substrate 16.

In this embodiment, the manufacturing a packaging layer includes arranging a first bearing film 62, arranging a first packaging layer 38 on the first bearing film 62, and then arranging a black optical layer 37 on the first packaging layer 38. It should be understood that in this embodiment, a process used for arranging an first packaging layer 38 on the first bearing film 62 and arranging a black optical layer 37 on the first packaging layer 38 may be flexibly selected. For example, the process may be, but not limited to, coating, silk-screen printing, printing, mold-pressing, or the like.

It should be understood that in this embodiment, the substrate and the packaging layer may be manufactured synchronously, or the substrate 16 is first manufactured and then the packaging layer is manufactured. Alternatively, the substrate and/or the packaging layer is directly purchased upstream.

It should be understood that the first packaging layer 38 and the black optical layer 37, which is also referred to as a black optical layer in the present invention, sequentially arranged on the first bearing film 62 in this step may be in a cured state, and are subsequently heated and converted from the cured state into a semi-cured state when being press-fit to the top surface of the main body of the substrate 16. Certainly, the first packaging layer 38 and the black optical layer 37 sequentially arranged on the first bearing film 62 in this step may alternatively be in the semi-cured state, and therefore are subsequently directly press-fit to the top surface of the main body of the substrate 16 easily. In this case, the press-fitting may be a hot press-fitting manner or another press-fitting manner. Details are not described herein again.
Step b3: press-fit a surface of the packaging layer provided with the black optical layer or a black optical layer 37 and the top surface of the substrate 16, where in a press-fitting process, the first packaging layer 38 and the black optical layer 37 sequentially arranged on the first bearing film 62 are in a semi-cured state, a top out-light surface of each of the LED chips are gradually exposed from the black optical layer 37, and the first packaging layer 38 covers the black optical layer 37 and the top out-light surface of each of the LED chips.

In an example of this embodiment, a surface of the packaging layer provided with the black optical layer or a black optical layer 37 may be press-fit to the top surface of the substrate 16 in a manner of, but not limited to, hot-pressing. In this case, a surface of the packaging layer provided with the black optical layer 37 may be laminated on the top surface of the substrate 16, and the packaging layer is heated and applied with pressure facing the main body of the substrate 16, to press-fit the packaging layer to the main body of the substrate 16. During the press-fitting, because the first packaging layer 38 and the black optical layer 37 are in a semi-melted state and are subjected to pressure facing the main body of the substrate 16, the top light-emitting surfaces of the LED chips are gradually exposed from the black optical layer 37.

In some examples of this embodiment, to improve the yield and the manufacturing efficiency, a substrate jig 6 may be provided, and the substrate jig 6 is provided with an accommodating cavity adapted for the substrate. When a surface of the packaging layer provided with the black optical layer is press-fit to the top surface of the substrate, the substrate may be fixed on the substrate jig 6. After the fixation, the main body of the substrate is fixedly arranged in the accommodating cavity of the substrate jig 6. In addition, the back surface of the substrate faces the bottom of the accommodating cavity, and the top surface of the substrate and the LED chips face a top opening of the accommodating cavity, to laminate the surface of the packaging layer provided with the black optical layer. In this example, before a surface of the packaging layer provided with the black optical layer is press-fit to the top surface of the substrate 16, electronic elements are first arranged on the back surface of the substrate 16. The bottom of the accommodating cavity is further provided with an accommodating groove corresponding to each electronic element. After the substrate is fixed on the substrate jig, each electronic element is located in a corresponding accommodating groove. It can be learned that the substrate jig used in this embodiment has a simple structure, is easy to manufacture, and has low costs.

It can be learned with reference to the foregoing manufacturing method that because the black optical layer used in this embodiment has a specific viscosity and is more easily bonded to the main body of the substrate and the LED chips, air-tightness can be improved, and the LED chips can be better protected; and during press-fitting, seams between the main body of the substrate and the LED chip and the like may be fully filled using fluidity of the black optical layer, and the contrast can be further improved.

Compared with a manner in which the black optical layer is first arranged on the main body of the substrate and then the first packaging layer first packaging layer is arranged on the black optical layer, this embodiment in which the first packaging layer and the black optical layer are sequentially arranged on the first bearing film and press-fit onto the main body of the substrate at a time can simplify the process, improve the manufacturing efficiency, and reduce the manufacturing costs. In addition, when the first packaging layer and the black optical layer are press-fit onto the main body of the substrate at a time, integrity of the black optical layer and the first packaging layer is better, to better help improve the press-fitting density. In addition, in this embodiment, it is not necessary to additionally spray a black ink layer or the like on the top surface of the substrate to set the top surface of the substrate in black, so that the manufacturing process can be further simplified, to reduce the manufacturing costs. In addition, because the black ink layer or the black optical layer is omitted, the thickness of the display panel can be reduced.

In some examples of this embodiment, the first bearing film in the packaging layer may be directly set as a transparent protection film. In this example, after a surface of the packaging layer provided with the black optical layer is press-fit to the top surface of the substrate, the first bearing film may be reserved, and the reserved first bearing film is the transparent protection film formed on the first packaging layer. In this case, it is not necessary to remove the first bearing film, and it is not necessary to additionally manufacture the transparent protection film on the first packaging layer either, so that the manufacturing process can be further simplified, to improve the manufacturing efficiency and reduce the costs.

Certainly, in some other examples of this embodiment, after a surface of the packaging layer provided with the black optical layer is press-fit to the top surface of the substrate, the first bearing film may alternatively be removed, and then one or more pre-fabricated adhesive sheets are sequentially laminated on the first packaging layer to form the transparent protection film. Certainly, the transparent protection film may alternatively be formed on the first packaging layer in a manner, but not limited to, coating, mold-pressing, silk-screen printing, or printing. In addition, in this example, the first bearing film may alternatively be replaced with a bearing substrate.

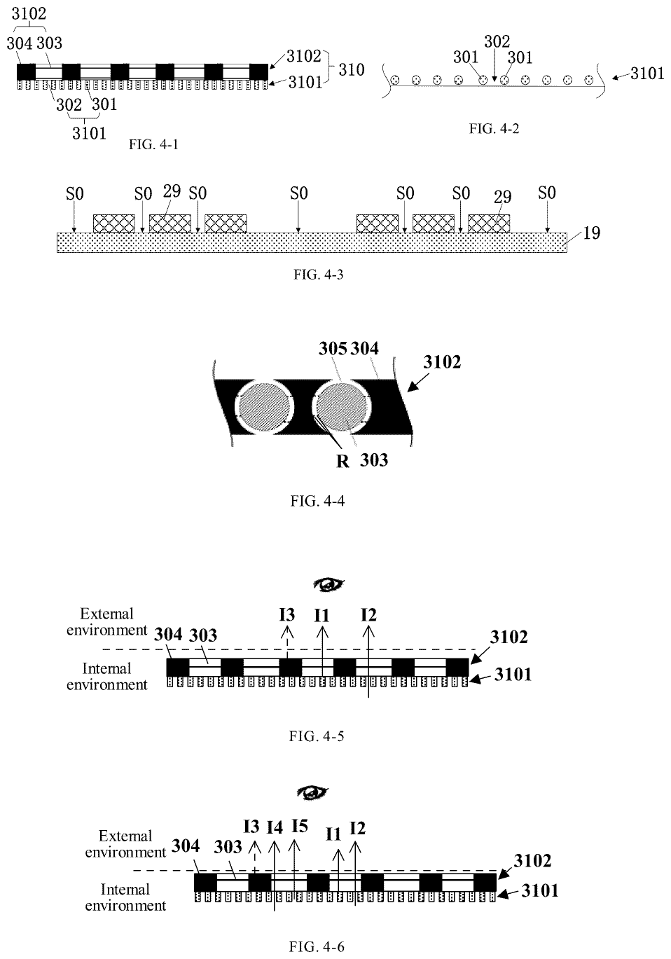

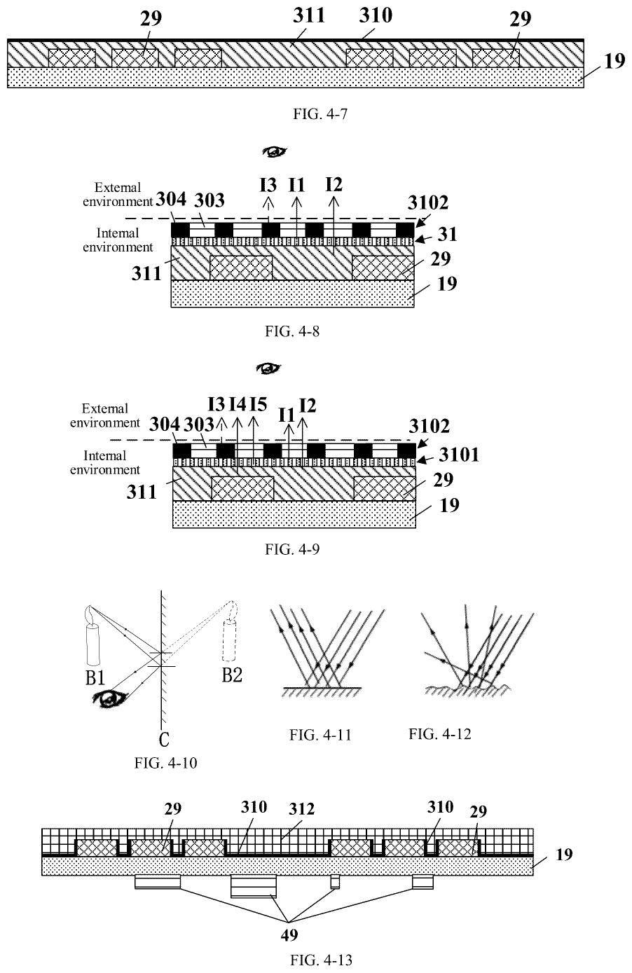

For case of understanding, this embodiment is described below using two manufacturing methods for the display module shown in FIG. 3-3 as examples. An exemplary manufacturing method is shown in FIG. 3-4, and includes, but not limited to:
Step a4: manufacture the packaging layer.

For example, in an example, a film sheet of the first bearing film 62 (the film sheet may be a transparent film) is laid flat first. The first bearing film 62 has a thickness range from 10 μm to 300 μm, a thickness evenness ranges from 1% to 10%, and a light transmittance range from 30% to 100%. Then, two layers of glue are sequentially arranged on the first bearing film 62. First, light-transmitting glue is arranged to form a first packaging layer 38. The first packaging layer 38 has a thickness range from 5 μm to 300 μm, a thickness evenness ranges from 1% to 10%, and a light transmittance range from 30% to 100%. Then, black adhesive is arranged on the first packaging layer 38 to form a black optical layer 37. The black optical layer 37 has a thickness range from 5 μm to 200 μm, a thickness evenness range from 1% to 10%, and a light transmittance range from 0% to 30%. The structure of the formed packaging layer is shown in FIG. 3-4. The black optical layer 37 and the first packaging layer 38 formed in step a4 in this example may be in a semi-cured state or a cured state.

In this example, a specific value of the thickness of the black optical layer 37 may be flexibly set based on ensuring as much as possible that the black optical layer 37 does not cover a top light-emitting surfaces of an LED chip 26 to cause low luminous efficiency thereof and enabling the black optical layer 37 to cover a side surface of the LED chip 26 as much as possible. Therefore, when the black optical layer 37 is press-fit to the top surface of the substrate, an outer surface 371 formed by a part suspended on the side surface of the LED chip 26 when the black optical layer 37 in the semi-cured state is compressed to run through the corresponding LED chip 26 is an inclined surface or a curved surface, to better avoid impact of crosstalk between the LED chips, thereby further improving the contrast and improving the yield.
Step b4: manufacture the substrate.

In an example, completing die bonding of an LED chip 26 on the top surface of the substrate is included. In this example, the LED chip 26 may be transferred onto the top surface of the substrate in various chip transfer manners (for example, a mass transfer manner), the LED chip 26 may be, but not limited to, a face-up, flip, or vertical LED chip, and an out-light color of the LED chip 26 may include at least one of red, green, blue, white, and the like. The pitch between the LED chips 26 ranges from 200 μm to 1000 μm.
Step c4: manufacture the substrate jig 6.

The substrate jig 6 in this example includes an accommodating cavity 61 adapted for the substrate, and the bottom of the accommodating cavity 61 in this example is not provided with an accommodating groove for accommodating an electronic element 46. In this embodiment, the material of the substrate jig may be, but not limited to, metal, ceramic, or another material. Details are not described herein again.
Step d4: fix the manufactured substrate on the substrate jig 6. The substrate jig 6 fixes the substrate, so that the substrate can be maintained in a steady state.
Step e4: laminate a surface of the packaging layer provided with the black optical layer 37 with the top surface of the substrate.
Step f4: heat and apply pressure facing the substrate 16 to the packaging layer, and press-fit the packaging layer to the substrate 16. During the press-fitting, because the black optical layer 37 is in a semi-melted state and is subjected to pressure facing the substrate 16, the top light-emitting surfaces of the LED chips 26 are gradually exposed from (that is, run through) the black optical layer 37. In addition, an outer surface 371 formed by a part suspended on the side surface of the LED chip 26 is an inclined surface or a curved surface. Refer to Step f4-1 and Step 4-2.
Step g4: after the black optical layer 37 and the first packaging layer 38 are cured, the substrate jig 6 is removed, and the electronic element 46 is arranged on the back surface of the substrate.

Another exemplary manufacturing method is shown in FIG. 3-5. includes, but not limited to:
Step a5: manufacture the substrate.

In this example, completing die bonding of an LED chip 26 on the top surface of the substrate is included, and the electronic element 46 is arranged on the back surface of the substrate.
Step b5: manufacture the substrate jig 6.

The substrate jig 6 in this example includes an accommodating cavity 61 adapted for the substrate, and the bottom of the accommodating cavity 61 in this example is provided with an accommodating groove 63 for accommodating an electronic element 46.
Step c5: fix the manufactured substrate on the substrate jig 6. The electronic element 46 on the back surface of the substrate 16 is accommodated in the accommodating groove 63. The substrate jig 6 fixes the substrate, so that the substrate can be maintained in a steady state.
Step d5: laminate a surface of the packaging layer (the packaging layer shown in FIG. 3-4 is still used in this example) provided with the black optical layer 37 with the top surface of the substrate.
Step e5: heat and apply pressure facing the substrate 16 to the packaging layer, and press-fit the packaging layer to the substrate 16. During the press-fitting, because the black optical layer 37 is in a semi-melted state and is subjected to pressure facing the substrate 16, the top light-emitting surfaces of the LED chips 26 are gradually exposed from (that is, run through) the black optical layer 37. Refer to Step e5-1 and Step e5-2.
Step f5: after the black optical layer 37 and the first packaging layer 38 are cured, the substrate jig 6 is removed, to obtain the display module.

In an application scenario of this embodiment, in the foregoing two exemplary manufacturing methods, when the first bearing film 62 is directly set as the transparent protection film 30, the transparent protection film 30 may be reserved. When the first bearing film 62 is not set as the transparent protection film 30, the transparent protection film 30 may be arranged on the first packaging layer 38 after the black optical layer 37 is press-fit onto the substrate 16 and after the first bearing film 62 is removed.

In the application scenarios of this embodiment, in the manufacturing methods of the two examples mentioned above, when the first carrier film 62 is directly set as the transparent protective layer, the transparent protective layer can be retained. However, when the first carrier film 62 is not set as the transparent protective layer, the first carrier film 62 can be removed after the black optical layer 37 is pressed onto the substrate 16, and the transparent protective layer can then be applied to the first packaging layer 38.

It can be learned that in the manufacturing method for a display module provided in this embodiment, an adhesive sheet production process may be used, and the top out-light surface of the LED chip in the COB LED technology is exposed from the black optical layer through press-fitting. Because the used black optical layer has specific viscosity and is more easily bonded to the main body of the substrate and the LED chips, air-tightness can be improved, and the LED chips can be better protected; and during press-fitting, seams between the main body of the substrate and the LED chip and the like may be fully filled using fluidity of the black optical layer. In this way, on the top surface of the substrate, other regions beyond the LED chips are all filled in black, and therefore the contrast can be further improved. In addition, the top out-light surface of the LED chip is covered by the first packaging layer, to reduce the light transmittance loss rate.

In addition, it is not necessary to additionally spray a black optical layer or the like on the top surface of the substrate to set the top surface of the substrate in black, so that the manufacturing process can be simplified, to reduce the manufacturing costs. In addition, because the black optical layer is omitted, the thickness of the display panel can be reduced. In addition, the transparent protection film is further arranged on the first packaging layer, so that the display performance can be optimized, and the protection effect can be improved. Therefore, the display module and the manufacturing method provided in this embodiment take into consideration high contrast, low light transmittance loss, and high protection performance.

### Embodiment 3

After an LED chip is soldered onto a substrate through a solder pad, a used tin solder paste becomes silver after being melted and covers a surface of the solder pad, and silver has a light reflection characteristic. As result, a display screen is insufficiently black when the screen is off, the contrast of the display screen is reduced, and the display effect is affected. For this problem, this embodiment further provides another packaging layer, display module, and manufacturing method therefore that can resolve this technical problem, and this embodiment may be implemented independently of other embodiments.

This embodiment provides a black optical layer composed of multiple sub-layers, forming a composite structure. The black optical layer is a semi-transparent layer (also referred to as a one-way perspective layer) and can be used in display modules and optical devices to enhance the display contrast and performance of the display module. Please refer to FIG. 4-1, which shows a schematic diagram of the black optical layer 310 in terms of optical path principles. This diagram is intended to illustrate the one-way perspective setup of the black optical layer for better understanding of the invention and is not a depiction of the actual structural design.

The black optical layer 310 includes a reflective layer 3101 and a black adhesive layer 3102 arranged on the reflective layer 3101. The reflective layer 3101 consists of reflective particles 301 and gaps between the reflective particles 301, which form the first light-transmission channels 302 through the reflective layer 3101. An embodiment of the structure of the reflective layer 3101 is shown in FIG. 4-1, where reflective particles 301 are laid flat on the bearing surface of the carrier (i.e., the adhesion surface of the reflective layer 3101). The gaps between the reflective particles 301 form individual first light-transmission channels 302. In this embodiment, the reflective particles 301 can exist in molecular form or other granular forms.

The reflection particles 301 in this embodiment may be arranged on the bearing surface through, but not limited to, a mature vacuum ion plating or evaporation process, manufacturing is simple, costs are low, and controllability is good. The reflection particles 301 in this embodiment may include at least one of various metal optical particles (which may include, for example but not limited to, at least one of nanometer-sized aluminum alloy particles, silver nitrate particles, Ag particles, Al particles, Rh particles, Cr particles, Pt particles, Cu particles, Au particles, and Ti particles, and preferably includes at least one of aluminum alloy particles and silver nitrate particles with low costs, a high reflection effect, and good commonality) and non-metal optical particles (which may include, for example but not limited to, at least one of nanometer-sized TiOz particles, ZnO particles, BaSO₄ particles, and AlzO₃ particles) with specific light reflection performance.

The reflection particles 301 in this embodiment may be particles with a particle size at a nanometer level, and the thickness of the reflection layer 3101 depends on the particle size of the reflection particles 301. For example, in some application examples, the reflection particles 301 may be, but not limited to, particles with a particle size ranging from 2 nanometers to 300 nanometers, and the thickness of the corresponding formed reflection layer 3101 ranges from 2 nanometers to 300 nanometers. Setting the thickness of the reflection layer 3101 at the nanometer level can better help reduce the thickness of the display module while improving the contrast, thereby better facilitating ultra thinning design of the display module. In some application scenarios, the reflection particles 301 may be specifically particles with a particle size ranging from 100 nanometers to 300 nanometers, and the thickness of the corresponding formed reflection layer 3101 ranges from 100 nanometers to 300 nanometers. For example, the particle size of the specifically used reflection particles 301 is 100 nanometers, 150 nanometers, 200 nanometers, 250 nanometers, or 300 nanometers. It should be understood that correspondingly, in this embodiment, the width and the height of each first light-transmitting channel 302 (that is, gap) are also at the nanometer level.

In this embodiment, as shown in FIG. 4-1 and FIG. 4-2, the first light-transmitting channels 302 of the reflection layer 3101 are formed and distributed in a similar matrix. In addition, to ensure good luminous efficiency to satisfy a display requirement while improving the contrast, in this embodiment, the first light-transmitting channels 302 are particle gaps in the reflection layer 3101, and the area occupied by the first light-transmitting channels 302 in an orthographic projection of the reflection layer 3101 is set to range from 60% to 70% of the area of the orthographic projection of the reflection layer 3101. For example, in some examples, a proportion of the area may be specifically set to 60%, 65%, or 70%. Correspondingly, the area occupied by the reflection particles 301 in the reflection layer 3101 in the orthographic projection of the reflection layer 3101 ranges from 30% to 40% of the area of the orthographic projection of the reflection layer 3101. This arrangement manner can greatly reduce the proportion of the reflection particles 301 and reduce use of the reflection particles 301, thereby helping reduce costs.

The black adhesive layer 3102 includes a transparent adhesive base material layer (the transparent adhesive base material layer is a bearing base layer used for bearing micron-sized glass beads and nanometer-sized black powder, not shown in FIG. 4-2), micron-sized glass beads 303 distributed in the transparent adhesive base material layer, and nanometer-sized black powder filling between the micron-sized glass beads 303, the nanometer-sized black powder is deposited on the micron-sized glass beads 303 to form a black light-blocking unit 304, and each of the micron-sized glass beads 303 forms a second light-transmitting channel for light to pass through the black adhesive layer 3102. In this example, positions of at least a part of the second light-transmitting channels and positions of at least a part of the first light-transmitting channels 302 may be arranged correspondingly to each other, so that light may pass through the second packaging layer 310 through the first light-transmitting channels 302 and the second light-transmitting channels at the corresponding positions. An exemplary schematic structural diagram of the black adhesive layer 3102 is shown in FIG. 4-4, and includes a transparent layer 305, micron-sized glass beads 303 distributed in the transparent adhesive base material layer 305, and nanometer-sized black powder distributed in the transparent layer 305 and filling between the micron-sized glass beads 303, and the nanometer-sized black powder is deposited together in the transparent layer to form a black light-blocking unit 304. In this embodiment, to avoid a case that the nanometer-sized black powder is attached to the micron-sized glass beads 303 to affect light transmission performance of the micron-sized glass beads 303, when the black adhesive layer 3102 is manufactured, the micron-sized glass beads 303 may be subjected to a charging operation to have negative charges, and the nanometer-sized black powder is also set to have negative charges (shown by R in FIG. 4-4). Therefore, the micron-sized glass beads 303 and the nanometer-sized black powder mixed in the transparent layer 305 may be repulsive to each other, that is, the micron-sized glass beads 303 may repulse the nanometer-sized black powder with negative charges, thereby preventing the nanometer-sized black powder from being attached onto the micron-sized glass beads 303, and the second light-transmitting channels formed by the micron-sized glass beads 303 is widened on a top surface and/or bottom surface of the black adhesive layer 3102.

In this embodiment, to ensure that the black adhesive layer 3102 can improve the contrast and can also ensure the specific luminous efficiency, the volume occupied by the micron-sized glass beads 303 in the black adhesive layer 3102 may be set to range from 50% to 70% of the volume of the black optical layer, and the proportion of the volume may be specifically set to 50%, 55%, 60%, 65%, or 70%. In other words, it may also be understood that the area occupied by the micron-sized glass beads 303 in the orthographic projection of the black adhesive layer 3102 may be set to range from 50% to 70% of the area of the orthographic projection of the black optical layer.

In this embodiment, the thickness of the black adhesive layer 3102 may be set to range from 50 microns to 100 microns. Setting the thickness of the black adhesive layer 3102 at the micron level can better help reduce the thickness of the translucent layer while improving the contrast, thereby facilitating ultra-thin design of the display module. In addition, to ensure that the micron-sized glass beads 303 can reliably form the second light-transmitting channels for light to pass through the black adhesive layer 3102, a ratio of the particle size of the micron-sized glass beads 303 to the thickness of the black adhesive layer 3102 may be set to range from 0.8 to 1.0, that is, the particle size of the micron-sized glass beads 303 may range, but not limited to, from 40 microns to 100 microns. For example, in some application scenarios, when a ratio of the particle size of the micron-sized glass beads 303 to the thickness of the black adhesive layer 3102 is set to 0.8, and the thickness of the black adhesive layer 3102 is 50 microns, the micron-sized glass beads 303 with the particle size of about 40 microns are used; when a ratio of the particle size of the micron-sized glass beads 303 to the thickness of the black adhesive layer 3102 is set to 0.9, and the thickness of the black adhesive layer 3102 is 100 microns, the micron-sized glass beads 303 with the particle size of about 90 microns are used; and when a ratio of the particle size of the micron-sized glass beads 303 to the thickness of the black adhesive layer 3102 is set to 1.0, and the thickness of the black adhesive layer 3102 is 100 microns, the micron-sized glass beads 303 with the particle size of about 100 microns are used. The glass beads may be made of a borosilicate raw material through a high technology, and have advantages such as light weight, low heat conduction, sound insulation, high dispersion, good electric insulation performance, good thermal stability, high strength, good chemical stability, and low costs. In addition, because the micron-sized glass beads 303 have low heat conduction performance and good thermal stability, heat generated by electronic elements on the top surface of the substrate during working and exported from the black adhesive layer 3102 can be further reduced, and stability of the black adhesive layer 3102 can be ensured.

It should be understood that the micron-sized glass beads 303 in this embodiment may be solid glass beads. However, in some application scenarios, the micron-sized glass beads 303 may be preferably micron-sized glass beads 303 in a hollow structure, and the micron-sized glass beads 303 in the hollow structure can further improve heat insulation performance of the black adhesive layer 3102, and can lighten the black adhesive layer 3102. When the micron-sized glass beads 303 in the hollow structure are used, the wall thickness of the micron-sized glass beads 303 may range, but not limited to, from 1 micron to 2 microns. The nanometer-sized black powder in this embodiment may include, but not limited to, nanometer-sized carbon black powder, and may be, but not limited to, nanometer-sized carbon black powder with the particle size ranging from 1 nanometer to 100 nanometers, so that a blackness of the black adhesive layer 3102 can be ensured. The transparent layer 305 in this embodiment may be, but not limited to, a transparent adhesive, and the transparent adhesive may be, but not limited to, polyester, polyvinyl chloride, modified epoxy, modified silica gel, or the like, and has advantages such as low costs and good commonality.

In this embodiment, a surface of the black adhesive layer 3102 far away from the reflection layer 3101 (that is, the top surface of the black adhesive layer 3102) may alternatively be treated according to a visual effect requirement. For example, in some application scenarios, when the black adhesive layer 3102 needs to be presented with a black mirror effect, the top surface of the black adhesive layer 3102 may be set as a smooth surface; and when the black adhesive layer 3102 needs to be prevented from being presented with a black mirror effect, the top surface of the black adhesive layer 3102 may be set as a non-smooth surface. The non-smooth surface may include, but not limited to, a fogged surface, a frosted surface, a matte surface, or a rough surface with different degrees of texture. Setting the top surface of the black adhesive layer 3102 as a non-smooth surface can cause light in an external environment to undergo diffuse reflection on the top surface of the black adhesive layer 3102, can reduce sharpness of an LED and reduce interference from ambient light, can reduce the mirror effect on the surface of the display module, thereby eliminating interference from external ambient light when the display module is illuminated, and achieving a better viewing effect while ensuring a high black contrast, and can be better applied to various application scenarios.

In this embodiment, the black optical layer can also be referred to as a semi-transparent layer, which covers at least the areas on the top side of substrate that are not covered by the orthogonal projections of the light-emitting units. The black optical layer is arranged on the top side of substrate, either directly adhering to the substrate or indirectly placed above it (i.e., with additional layer structures between the black optical layer and the top side of the substrate). In this embodiment, covering the areas on the top side of the substrate that are not covered by the orthogonal projections of the light-emitting units means that, apart from the projection-covered areas of the light-emitting units, all other areas on the top side of the substrate are covered by the black optical layer. For example, as shown in FIG. 4-3, a display module consists of a substrate 19 with several light-emitting units 29 arranged on its top side. The areas on the top side of substrate 19 that are not covered by the orthogonal projections of the light-emitting units 29 are represented by the regions marked SO in FIG. 4-3. This design enhances the contrast of the display module and improves its display performance.

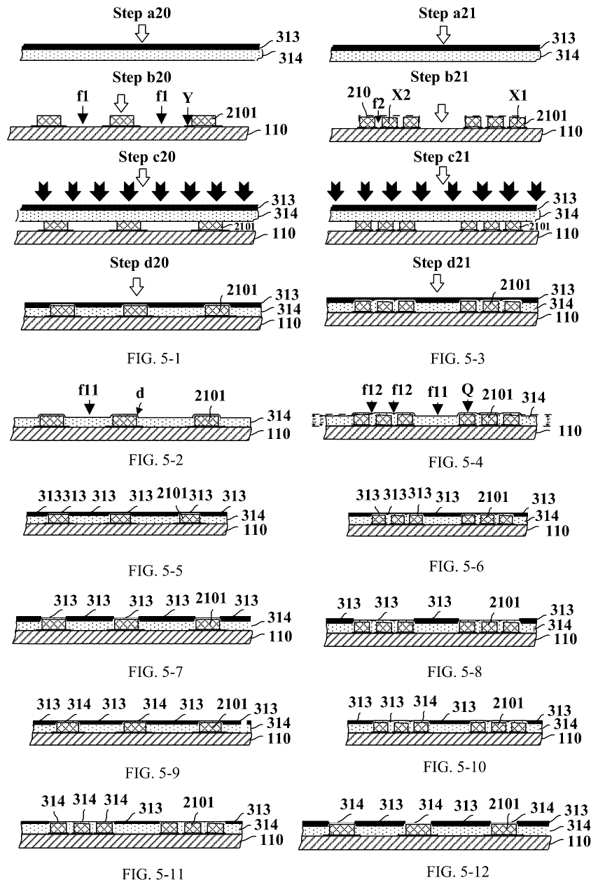

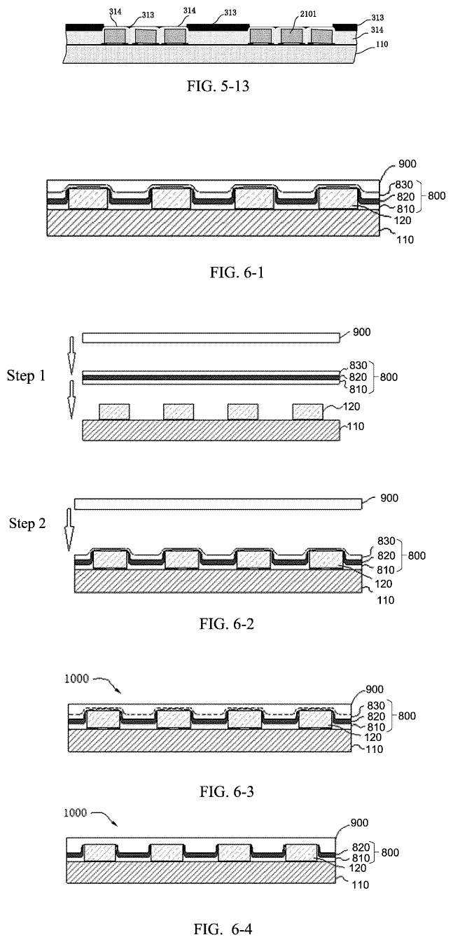

The foregoing second packaging layer used in this embodiment has a visually unidirectional perspective effect, that is, in a scenario in which the strength of external ambient light of the display module is greater than or equal to 1.5 times the strength of internal ambient light of the display module, a region in the display module covered by the second packaging layer is presented in black in human vision, and therefore the contrast can be improved; otherwise, when the luminance of internal light of the display module is greater than 1.5 times the luminance of external light of the display module, the display module can implement normal display. For example, as shown in FIG. 4-5, when the light-emitting units do not emit light, that is, the display module is off, no light is generated in the internal environment, and light that human eyes can view mainly includes the following three parts theoretically: light I1 that is in external ambient light and is reflected by the reflection particles in the reflection layer 3101; light I2 in the internal environment reflected and absorbed for a plurality of times and then returning to the external environment after a small part of external ambient light enters the internal environment through the first light-transmitting channels and the second light-transmitting channels corresponding to each other; and external ambient light absorbed by the black light-blocking unit 304 in the black adhesive layer 3102, where the light is absorbed and therefore is visually black I3. According to a unidirectional perspective principle, when the luminance of the external ambient light is greater than 1.5 times the luminance of the internal environment, human vision ignores the received internal ambient light, and in FIG. 4-5, the strength of the light I2 is far less than the strength of the light I1. In this case, a region covered by the second packaging layer 310 is presented in black in human vision.

as shown in FIG. 4-6, when the light-emitting units emit light, that is, the display module is on, the light-emitting units in the internal environment generate light, and light that human eyes can view mainly includes the following five parts theoretically: light I1 that is in external ambient light and is reflected by the reflection particles in the reflection layer 3101; light I2 in the internal environment reflected and absorbed for a plurality of times and then returning to the external environment after a small part of external ambient light enters the internal environment through the first light-transmitting channels and the second light-transmitting channels corresponding to each other; and external ambient light absorbed by the black light-blocking unit 304 in the black adhesive layer 3102, where the light is absorbed and therefore is visually black I3; light I4 generated by the light-emitting units and directly incident to the external environment from the first light-transmitting channels and the second light-transmitting channels corresponding to each other; and light I5 generated by the LED, and reflected and absorbed in the internal environment for a plurality of times and then incident to the external environment from the first light-transmitting channels and the second light-transmitting channels corresponding to each other. Generally, luminance of the display screen reaching a range from 300 nit to 500 nit can achieve a very good display effect, and luminance of light emitted by the LED, that is, I4+I5 can reach a range from 800 nit to 2000 nit, greater than the range from 300 to 500 nit. In this case, human vision can completely view content displayed on the LED display screen.

As described above, in this embodiment, the second packaging layer 310 may be indirectly arranged on the top surface of the substrate 19 or directly attached to the top surface of the substrate 19. For case of understanding, this embodiment is described below with reference to several exemplary structures shown in accompanying drawings.

In an example in which the second packaging layer is indirectly arranged on the top surface of the substrate, the display module may further include an eleventh packaging layer arranged between the top surface of the substrate and a translucent layer. The eleventh packaging layer in this embodiment is a light-transmitting layer. It should be understood that the forming process and the material of the eleventh packaging layer in this embodiment may be flexibly set, which is not limited. For example, in some examples, the eleventh packaging layer may be, but not limited to, an adhesive layer, and may be formed in a manner of, but not limited to, coating, mold-pressing, printing, or mounting after being manufactured into a film in advance. The eleventh packaging layer in this embodiment can play a role in resisting water, resisting moisture, and resisting collision, can protect the light-emitting units, and can be used as a substrate on which the translucent layer is arranged. For example, in some application examples, the packaging layer may be a transparent layer made of transparent epoxy glue, thereby sealing and protecting the light-emitting units on the substrate. In some application scenarios, at least one of white powder (for example, including, but not limited to, SiO2 powder), a melanin, and light diffusion particles may be added to the transparent epoxy glue according to a requirement, thereby further adjusting the out-light effect of the display module. In addition, in this embodiment, an upper surface of the packaging layer (that is, a surface of the packaging layer far away from the top surface of the substrate) may be set as a matte surface, a shiny surface, a frosted surface, a fogged surface, or the like according to a requirement, thereby achieving different appearance effects and out-light effects, and further enriching display effects and improving user experience satisfaction.

An exemplary structure in which the second packaging layer is indirectly arranged on the top surface of the substrate is shown in FIG. 4-7, and includes a substrate 19, a plurality of light-emitting units 29 arranged on a top surface of the substrate 19, and packaging layer 311 arranged on the top surface of the substrate 19 and covering each light-emitting unit 29. In this embodiment, the light-emitting unit 29 has a surface far away from the top surface of the substrate as a top out-light surface, a surface close to the top surface of the substrate as a bottom surface, and surfaces located between the top out-light surface and the bottom surface as side surfaces. The display module further includes a second packaging layer 310 formed on the packaging layer 311. In this example, the second packaging layer 310 covers regions that are on the top surface of the substrate 19 and are not covered by orthographic projections of the light-emitting unit 29, and also covers the top light-emitting surfaces of the light-emitting units 29, that is, in this example, the second packaging layer 310 completely covers the packaging layer. When the light-emitting units 29 of the display module in this example do not emit light, that is, are off, a schematic model of light paths is shown in FIG. 4-8, and when emitting light, a schematic model of light paths is shown in FIG. 4-9. For case of understanding, this embodiment is exemplified below with reference to some concepts in the existing display field in such a scenario in which a display module is applied to a display screen.

The existing LCD display refers to the commonly used LCD display currently available, with a typical brightness of 350 nits and generally a maximum brightness of 500 nits. The existing liquid crystal display screen has low luminance. However, because a light filter is arranged in the structure, and the light filter has a black matrix, the liquid crystal display screen can display high black when being off, and the contrast of the existing liquid crystal display screen is actually the best among all current types of display screens. To be specific, although the luminance is low, an ultra high black contrast can still be reached as long as a ratio of off-screen black luminance to on-screen highest luminance is sufficiently large. For an ordinary COB display screen, solder pads are exposed, natural light reflected by a silver tin paste on surfaces of the solder pads is viewed by human eyes when the screen is off, and a mirror surface cannot be formed since the surface of the tin paste is uneven. Therefore, silver is viewed by the human eyes. It may be learned according to the foregoing analysis that the second packaging layer 310 arranged in this embodiment blocks all silver, and when the screen is off, because of the unidirectional perspective principle, human eyes can view only the second packaging layer 310 to block the silver solder pads, and the second packaging layer 310 is highly black, thereby improving the black contrast.

Descriptions about light received by human eyes in FIG. 4-5 and FIG. 4-8: When the light-emitting units do not emit light (that is, the screen is off), human eyes receive light I1+I2. I3 is light absorbed by black, and is presented in black in human vision, and therefore is represented with a dashed line. If external natural light is represented as I-out, I1, I2, and I3 are three parts into which the external natural light is divided, where a part is directly reflected by the reflection layer and received by the human eyes, that is, I1, a part enters an internal environment, returns to an external environment after being reflected and absorbed for a plurality of times, and then is received by the human eyes, that is, I2, and a part is directly absorbed by black, that is, I3, so that I-out>1.5*(I1+I2+I3). Therefore, a region covered by the second packaging layer 310 is presented in black in human vision. The second packaging layer 310 may be visually used as a black mirror when the top surface of the black adhesive layer 3102 is a smooth surface.

Descriptions about light received by human eyes in FIG. 4-6 and FIG. 4-9: when the light-emitting units emit light, light emitted by the LED is divided into two parts to be received by the human eyes, that is, I4+I5; and it may be learned with reference to the foregoing proportion of the first light-transmitting channels and the second light-transmitting channels that, a minimum value of I4+I5 may be greater than 50% of luminance of the light emitted by the LED. If the luminance of the light emitted by the LED is represented as I-in, I-in>I4+I5>50% of I-in, and 50% of I-in may range from 400 nit to 1000 nit. Therefore, I4+I5>300 nit. In this case, the user can obtain a complete display effect.

Regarding the explanation that the top surface of the black adhesive layer 3102, when it is smooth, can visually make the black optical layer 310 appear as a black mirror: First, the principle of the mirror is shown in FIG. 4-10. The light emitted by candle B1 is reflected by the smooth reflective layer in mirror C. The human eye receives the reflected light, and the brain perceives an image of candle B2, creating the illusion of a candle in the mirror. This phenomenon is known as the principle of specular reflection.

As shown in FIGS. 4-5 and 4-9, the micron-level glass microspheres in the black adhesive layer 3102 are glass crystals, and the reflective layer 3101 contains reflective particles. When the light-emitting unit is not emitting light, the micron-level glass microspheres and reflective particles form a mirror. However, due to the presence of black light-blocking units 304 in the black adhesive layer 3102, it can be imagined as a mirror with an ultra-black matrix composed of black light-blocking units 304. Since the glass microspheres are micron-level crystals, they visually appear as a black mirror to the human eye.

In this embodiment, the top surface of the black adhesive layer 3102 is set as a non-smooth surface to create diffuse reflection on the surface. As shown in FIG. 4-11, when the top surface of the black adhesive layer 3102 is smooth, specular reflection occurs, as illustrated in FIG. 4-11. However, when the top surface of the black adhesive layer 3102 is a non-smooth surface, such as the rough surface shown in FIG. 4-12, diffuse reflection occurs, as illustrated in FIG. 4-12. In this case, the human eye does not perceive a complete mirror image (which can be understood as a matte screen). Since diffuse reflection prevents the formation of a clear mirror image, it helps to reduce ambient light interference and improve the display performance.

This embodiment also provides a display screen that includes at least one of the display modules mentioned in the above embodiments. For case of understanding, this embodiment will be explained using the display module shown in FIG. 4-13 as an example. In this display screen, the driving element 49 is installed on the back side of substrate 19 and is electrically connected to the light-emitting units 29 on the top side of the substrate, driving the operation of the light-emitting units 29. Additionally, in some application scenarios of this example, other electronic components, besides the light-emitting unit 29, can be flexibly arranged on the top side and/or back side of the substrate 19. The installed electronic components may include, but are not limited to, resistors, capacitors, and others, which can be selected based on specific application requirements.

### Embodiment 4

This embodiment provides a display module and a manufacturing method for a display module that can resolve a problem of reducing contrast of a display screen because a surface of a solder pad is covered by a silver tin paste and can also prevent a black adhesive from remaining on a top out-light surface of an LED chip. In addition, this embodiment may be individually implemented independently of other embodiments.

The manufacturing method for a display module provided in this embodiment includes, but not limited to:
Step a 19: manufacture a substrate and a packaging layer.

The manufacturing of a substrate in this embodiment includes, but not limited to: providing a substrate, and fixing a plurality of light-emitting units on a top surface of the substrate, where a gap is provided between adjacent light-emitting units. In this embodiment, one light-emitting unit includes a plurality of LED chips, and an electrode of each LED chip is soldered to corresponding solder pads on the substrate; and a silver outer surface formed after LED chips of each light-emitting unit are soldered to solder pads is mainly distributed in the gap f1. It should be understood that in this embodiment, other electronic elements may be first arranged on the top surface and/or the back surface of the substrate, and then the packaging layer is arranged on the substrate; or after the light-emitting units and the packaging layer are arranged on the top surface of the substrate, electronic elements are arranged on the back surface of the substrate.

In this embodiment, the manufacturing of a packaging layer includes: providing a black optical layer and a first packaging layer superposed together. In this example, when the packaging layer is manufactured, the black optical layer may be first formed, and then the first packaging layer is formed on the black optical layer; or the first packaging layer may be first formed, and then the black optical layer is formed on the first packaging layer. Regardless of a manner which is used, when press-fitting is performed using a hot-pressing process, the black optical layer is oriented to the top surface of the substrate (that is, a surface of the black optical layer far away from the first packaging layer is oriented to the top surface of the substrate), and the black optical layer and the first packaging layer are press-fit together onto the top surface of the substrate. In this embodiment, processes used for forming the black optical layer and the first packaging layer are not limited, and the process used for forming the black optical layer process may be the same as or different from the process used for forming the first packaging layer. The specific used processes may be, but not limited to, coating, silk-screen printing, printing, or mold-pressing. In this embodiment, the substrate and the packaging layer may be manufactured synchronously, or the substrate is first manufactured and then the packaging layer is manufactured. Alternatively, the substrate and/or the packaging layer are/is directly purchased from an upstream.

The black optical layer and the first packaging layer formed in this embodiment may be in and be maintained in a semi-cured state, and therefore are subsequently directly press-fit to the top surface of the substrate easily. In addition, this embodiment is not limited to a hot-pressing process using an adhesive. For example, when being in and maintained in a specific semi-cured state, the black optical layer and the first packaging layer that are formed may be directly press-fit and do not need to be heated. This manner is an equivalent alternative manner of the hot-pressing process in this embodiment.
Step b19: press-fit the black optical layer and the first packaging layer together on the top surface of the substrate through a hot-pressing process.

In this embodiment, after the black optical layer and the first packaging layer are press-fit together on the top surface of the substrate through the hot-pressing process, the black optical layer covers the top surface of the substrate and a top out-light surface of each of the LED chips, and forms a concave portion in the gap between the adjacent light-emitting units, and a part of the first packaging layer fills in the concave portion to cover at least the concave portion (that is, completely cover at least the concave portion). In this embodiment, the top light-emitting surfaces of the LED chips are surfaces of the LED chips far away from the top surface of the substrate.

For example, the black optical layer is oriented to the top surface of the substrate and is laminated with the top light-emitting surfaces of the LED chips on the top surface of the substrate and then hot-pressed. During press-fitting, the black optical layer and the first packaging layer are in a semi-cured state, and the transparent layer and the first packaging layer are pressed and gradually approach the top surface of the substrate, until the black optical layer is laminated with the top surface of the substrate. The LED chips located on the top surface of the substrate are covered by the black optical layer, the top light-emitting surfaces of the LED chips are also covered by the black optical layer, and the black optical layer forms the concave portion in the gap between the adjacent light-emitting units. After the first packaging layer on the black optical layer is press-fit, at least each concave portion is filled, thereby covering the silver outer surface on the solder pad. Therefore, the contrast of the display module can be improved, to improve the display effect. In addition, because the black optical layer covers the top light-emitting surfaces of the LED chips, and the first packaging layer does not contact the top light-emitting surfaces of the LED chips during press-fitting, that is, is impossible to directly remain on the top light-emitting surfaces of the LED chips, light-emitting characteristics of the LED chips can be ensured. In addition, during the foregoing press-fitting, the black optical layer is located between the first packaging layer and the substrate to serve as a buffer layer. Even if one or more LED chips are inclined on the top surface of the substrate during the foregoing fixation, the black optical layer can still form one flat surface as much as possible in regions right above the LED chips, thereby improving consistency of the press-fit first packaging layer between the regions on the black optical layer, to further improve consistency between out-light effects. In addition, the black optical layer and the first packaging layer are press-fit together onto the top surface of the substrate, and the black optical layer and the first packaging layer do not need to be separately press-fit at two times, which can improve the manufacturing efficiency.

In addition, the used hot-pressing process is simple and mature, which can further ensure and improve the yield, and facilitate control of the manufacturing costs.

For case of understanding, a specific example of a manufacturing method for a display module is described below. As shown in FIG. 5-1, the manufacturing method for a display module in this example includes, but not limited to:
Step a20: Fabricating the packaging layer, which includes forming the black optical layer 313 and the first packaging layer 314 stacked on the black optical layer 313. As shown in FIG. 5-1, from a positional relationship perspective, the first packaging layer 314 is located above the black optical layer 313. However, it should be understood that during fabrication, the first packaging layer 314 can be formed first, followed by the black optical layer 313 on top of it. Alternatively, the black optical layer 313 can be formed first, with the first packaging layer 314 subsequently applied on top of the black optical layer 313.
Step b20: manufacture a substrate. For example, refer to a substrate shown in FIG. 5-1, where a plurality of light-emitting units is arranged on the substrate 110, a gap f1 is provided between adjacent light-emitting units, and a main part of a silver outer surface Y formed during soldering is in the gap f1.
Step c20: laminate the black optical layer 313 and the first packaging layer 314 together onto LED chips 2101 arranged on a top surface of the substrate 110, and then perform press-fitting using a hot-pressing process. A surface of the black optical layer 313 far away from the first packaging layer 314 is oriented to the substrate 110.
Step d20: press-fit the black optical layer 313 and the first packaging layer 314 onto the top surface of the substrate 110, and then cover the top surface of the substrate 110 and the LED chips 2101 with the black optical layer 313. The first packaging layer 314 forms a concave portion in the gap between the adjacent light-emitting units. A schematic diagram of the concave portion is shown in FIG. 5-2 (FIG. 5-2 shows a structure remaining after the black optical layer is removed from the display module obtained after the press-fitting of step d20 in FIG. 5-1), FIG. 5-2 shows a concave portion f11 formed between the light-emitting units. A side wall of the concave portion f11 includes a curved surface d formed by fluidity of the first packaging layer 314, and formation of the curved surface d can further increase the lamination area between the black optical layer 313 and the first packaging layer 314, thereby improving the bonding strength between the two packaging layers.

As shown in FIG. 5-1 and FIG. 5-2, in this example, after the press-fitting, the first packaging layer 314 covers each concave portion f11, and each silver outer surface Y is covered by the first packaging layer 314, which can improve the contrast of the display module, and improve the display effect. In addition, the LED chips 2101 are covered by the first packaging layer 314, the black optical layer 313 covers the first packaging layer 314, and the black optical layer 313 does not contact the LED chips 2101. Therefore, the black optical layer 313 does not remain on the LED chips 2101, which can ensure light-emitting characteristics of the LED chips 2101.

In addition, in step c20, the black optical layer 313 and the first packaging layer 314 are press-fit together onto the top surface of the substrate, which can simplify the manufacturing process, and improve the manufacturing efficiency. In addition, the used hot-pressing process is simple and mature, which can further ensure and improve the yield, and facilitate control of the manufacturing costs.

For ease of understanding, this embodiment is described below using an example in which the same manufacturing process as that in FIG. 5-1 is used in a cross-sectional view of a substrate in another direction. Specifically, as shown in FIG. 5-3, step a21 to step d21 in FIG. 5-3 are the same as step a20 to step d20 in FIG. 5-1 respectively. Details are not described herein again. As shown in step b21 in FIG. 5-3, it is assumed that LED chips X1 and X2 are inclined during soldering. FIG. 5-4 shows a structure remaining after the first packaging layer is removed from the display module obtained after the press-fitting in FIG. 5-3. As shown in FIG. 5-3 and FIG. 5-4, regions of the first packaging layer 314 right above the light emitting surfaces of the LED chips 2101 can also form one flat surface Q, that is, the first packaging layer 314 is used to compensate for unevenness caused by inclination of the LED chips X1 and X2 as much as possible, thereby ensuring consistency of the black optical layer 313 between the regions on the first packaging layer 314, and improving consistency between light emitting effects of modules.

As shown in FIG. 5-1 and FIG. 5-3, in this example, each light-emitting unit contains multiple LED chips. A gap f2 is provided between adjacent LED chips 2101 in each light-emitting unit 210, and the width of the gap f2 between LED chips 2101 is less than the width of the gap f1 between the light-emitting unit 210. In addition, it should be understood that in the display field, the width of the gap f2 is generally far less than the width of the gap f1, and a specific difference between the two may be flexibly set according to a specific application scenario and is not limited herein.

In this example, as shown in FIG. 5-3 and FIG. 5-4, after the black optical layer 313 and the first packaging layer 314 are press-fit together on the top surface of the substrate through a hot-pressing process, a region of the first packaging layer 314 on the gap between LED chip f2 forms a concave portion f12, the black optical layer 313 fills in the concave portion f12 and completely covers a top surface of the first packaging layer 314, and the top surface of the black optical layer 313 is a surface thereof far away from the substrate 110. As shown in FIG. 5-4, a distance h2 from the lowest point of the concave portion f12 to the top surface of the substrate is greater than a distance h1 from the light emitting surface of the LED chip 2101 to the top surface of the substrate. To be specific, in this example, the thickness of the first packaging layer 314 filled in the concave portion f12 is greater than the thickness of the LED chip 2101.

In one application scenario of this example, as shown in FIGS. 5-3 and 5-4, the black optical layer 313 and the first packaging layer 314 are simultaneously press-fitted onto the top side of the substrate 110 through a hot-pressing process. After this process, the fourth distance h3 from the bottom of the recessed part f11 to the top side of the substrate 110 is less than the second distance h1, which is the distance from the top out-light surface of the LED chip 2101 to the top side of the substrate 110. For example, in some scenarios, h3 can be set to be less than or equal to ⅔×h1. This structural design minimizes the overall thickness of the display module as much as possible, facilitating the slim and lightweight design of the display screen. It also improves the utilization of adhesive materials and reduces manufacturing costs. In specific display module structures, h3 can be set to ⅓×h1, ½×h1, or ⅔×h1, with the preferred range being greater than or equal to ½×h1 and less than or equal to ⅔×h1. This configuration reduces the need for precise thickness control of the black optical layer 313 and relaxes the process accuracy requirements.

In some application scenarios of this example, based on a condition that the first packaging layer 314 is set to satisfy display contrast performance, the first packaging layer 314 may be further set to have specific light transmission performance. In the present invention scenario, after a display module is manufactured through the manufacturing method shown in FIG. 5-1 or FIG. 5-3, no treatment may be performed on the first packaging layer 314, thereby simplifying the manufacturing process and improving the manufacturing efficiency.

Certainly, in some examples, even if the first packaging layer 314 has a certain degree of light transmittance, a portion of the first packaging layer 314 directly above the top out-light surface of each LED chip 2101 may be removed after the display module is fabricated to further improve the light-emission efficiency. For example, in one application scenario, as shown in FIG. 5-5, a portion of the first packaging layer 314 from the display module obtained in FIG. 5-1 is removed to make the first packaging layer 314 thinner, thereby enhancing light-emission efficiency. After removal, the top surface of the first packaging layer 314 still covers the black optical layer 313 above the top out-light surface of each LED chip 2101, and the top surface of the first packaging layer 314 remains a flat plane. The display module shown in FIG. 5-5 can use various processes, such as grinding, to partially remove the first packaging layer 314. In this application scenario, FIG. 5-6 illustrates the display module obtained after partially removing the first packaging layer 314 from the module shown in FIG. 5-3. Even after removal, the top surface of the first packaging layer 314 still covers the black optical layer 313 over the top out-light surfaces of the LED chips 2101, including the recessed parts f11 and f12. The top surface of the first packaging layer 314 remains a flat plane.

For another application scenario, refer to display modules shown in FIG. 5-7 and FIG. 5-8. FIG. 5-7 shows the partial removal of the black optical layer 313 disposed on the light-emitting surface of LED chips in the display module of FIG. 5-1 and FIG. 5-8 shows the partial removal of the black optical layer 313 disposed on the light-emitting surface of LED chips in the display module of FIG. 11-3, so that the black optical layer 313 right above the light-emitting surfaces of the LED chips 2101 is thinner than the thickness of the black optical layer 313 in the display modules shown in FIG. 5-1 and FIG. 5-3, to improve the luminous efficiency. In this scenario, the first packaging layer 314 may be removed using, but not limited to, by an etching process.

In this embodiment, when the first packaging layer 314 possesses a certain degree of light transmittance, regardless of whether the removal steps shown in FIGS. 5-5 to 5-8 are applied, the light transmittance of the remaining portion of the first packaging layer on the top out-light surface of each LED chip 2101 should be set to 40% or higher to ensure the brightness and display performance of the module.

In another example of this embodiment, the manufacturing method for a display module may further include, but not limited to:
After the black optical layer 313 and the first packaging layer 314 are press-fit together on the top surface of the substrate through the hot-pressing process, further completely removing the first packaging layer 314 right above the light-emitting surfaces of the LED chips 2101.

For example, in some application scenarios, the completely removing the black optical layer 313 right above the light-emitting surfaces of the LED chips 2101 includes: completely removing the black adhesive disposed on the region of the concave portion f12, where after the removing, the black optical layer 313 is flush with the first packaging layer 314 on the light-emitting surfaces of the LED chips. For example, for an application scenario, refer to a display module shown in FIG. 5-9. Remove a portion of the overall black optical layer 313 of FIG. 5-1, until a part of the first packaging layer 314 above the light emitting surface of LED chips 2101 is exposed. After the removing, the black optical layer 313 is flush with the first packaging layer 314 on the light-emitting surfaces of the LED chips 2101. In the present invention scenario, a schematic diagram of the whole first packaging layer 314 in the display module obtained in FIG. 5-3 with a part removed is shown in FIG. 5-10. The first packaging layer 314 above the emitting surface of each LED chip 2101 is exposed to the black optical layer 313, and the removed black optical layer 313 still fills the concave f12 and is flush with the first packaging layer 314 on the light-emitting surfaces of the LED chips 2101. In the examples shown in FIG. 5-9 and FIG. 5-10, after the removing, the black optical layer 313 still covers the first packaging layer 314 on edge regions of the light-emitting surfaces of the LED chips 2101, so that the black optical layer 313 may cover a silver outer surface Y existing between the LED chips 2101 in the light-emitting units as much as possible, thereby further improving the display contrast of the module.

In this example, another example of completely removing the black adhesive located in the concave portion f12 is shown in FIG. 5-11. In contrast to the removal method shown in FIG. 5-10, the difference lies in that when removing the black optical layer 313, it is removed until the black optical layer 313 has a difference that the black optical layer 313 is removed, until the black optical layer 313 located in the concave portion f12 is also completely removed (it may be learned from FIG. 5-11 that the concave portion f12 on the first packaging layer 314 is also completely removed), after the removing, the black optical layer 313 is flush with the first packaging layer 314 on the light-emitting surfaces of the LED chips 2101, and the concave portion f12 does not exist on the first packaging layer 314 anymore. Compared with the example shown in FIG. 5-10, the black optical layer 313 and the first packaging layer 314 have a smaller whole thickness, to better facilitate lightening and thinning of the module.

The black adhesive of the black optical layer 313 located in the concave portion f12 may alternatively be completely removed in a local removing manner. For example, as shown in FIG. 5-12, the black adhesive of the black optical layer 313 in the display module shown in FIG. 5-1 located above the light-emitting surfaces of the LED chips 2101 is locally completely removed; and in FIG. 5-13, the black adhesive of black optical layer 313 in the display module shown in FIG. 5-3 located right above the light-emitting surfaces of the LED chips 2101 is locally completely removed.

In the foregoing examples of this embodiment, the locally removing the black optical layer 313 can improve the removing efficiency of the black optical layer 313. In addition, in the examples shown in FIG. 5-9 to FIG. 5-13, the black optical layer 313 may have a light transmission characteristic or have no light transmission characteristic, and the black optical layer 313 has more flexible material selection and wider applicability.

In still some other examples of this embodiment, to improve the yield and the manufacturing efficiency, a substrate jig may be provided, and the substrate jig is provided with an accommodating cavity adapted for the substrate. When the black optical layer and the first packaging layer are press-fit to the top surface of the substrate, the substrate may be fixed on the substrate jig. After the fixation, the substrate is fixedly arranged in the accommodating cavity of the substrate jig. In addition, the back surface of the substrate faces the bottom of the accommodating cavity, and the top surface of the substrate and the LED chips face a top opening of the accommodating cavity, to laminate the black optical layer. In this example, before the black optical layer is press-fit to the top surface of the substrate, other electronic elements are first arranged on the back surface of the substrate. The bottom of the accommodating cavity is further provided with an accommodating groove corresponding to each electronic element. After the substrate is fixed on the substrate jig, each electronic element is located in a corresponding accommodating groove. It can be learned that the substrate jig used in this embodiment has a simple structure, is easy to manufacture, and has low costs.

It can be learned that in the manufacturing method for a display module provided in this embodiment, the process is simple, the efficiency is high, costs are low, the display contrast of the manufactured display module is good, and the first packaging layer included in the display module has good consistency and does not remain on the light-emitting surfaces of the LED chips. This embodiment further provides a display screen. The display screen is manufactured through at least one manufacturing method for a display module in the foregoing examples. It can be learned that the display screen provided in this embodiment has good black contrast, the manufacturing process is simple, impact on flatness of the LED chips after the LED chips are fixed onto the substrate is reduced, the yield is high, and costs are low.

### Embodiment 5

This embodiment provides a display module further equipped with a composite black optical film. The distinction from previous designs lies in configuring the black optical film as a composite black optical film. When the transparent protective layer is applied and press-fitted onto the surface of the composite black optical film, it reduces or prevents any residual black optical layer from remaining on top of the LED chips, thereby reducing obstruction of the light-emitting surface.

An exemplary display module provided in this embodiment is shown in FIG. 6-1. This embodiment provides a substrate 110, on which multiple LED chips 120 are arranged. A lower light-transmitting layer 810 is configured on the substrate 110, and a black optical layer 820 is arranged on top of the lower light-transmitting layer 810. Additionally, an upper light-transmitting layer 830 and a transparent protective layer 900 are arranged on the black optical layer 820. The lower light-transmitting layer 810 at least covers the area between the multiple LED chips 120 on the top surface of the substrate 110. In the area between the LED chips 120, the top surface of the lower light-transmitting layer 810 is lower than the top surfaces of the LED chips 120. The black optical layer 820 covers the top surface of the lower light-transmitting layer 810, and its top surface is also lower than the top surfaces of the LED chips 120. The transparent protective layer 900 covers both the top surface of the black optical layer 820 and the top surfaces of the LED chips 120.

In the embodiment, due to the LED chips 120 press against the lower light-transmitting layer 810 and the black optical layer 820, causing the layers to bend upward around the sides of the LED chips 120. The LED chips 120 penetrate at least through the black optical layer 820. The black optical layer 820 does not come into direct contact with the LED chips 120, as the lower light-transmitting layer 810 acts as a barrier between them. In other embodiments, due to differences in manufacturing materials and processes, the black optical layer 820 on the peripheral side of the light-emitting element 120 may also come into contact with the side of the light-emitting element. In other embodiments, due to differences in manufacturing materials and processes, the black optical layer 820 on the peripheral side of the light-emitting element may neither tilt upward, curve downward, nor remain level relative to the light-emitting element.

In another embodiment of this implementation, as shown in FIG. 6-3, the transparent protective film 900 and the upper light-transmitting layer 830 of the composite black optical film 800 are made of the same material. When the transparent protective film 900 is applied and pressed onto the surface of the upper light-transmitting layer 830, it integrates seamlessly with the upper light-transmitting layer 830. This design prevents delamination between the transparent protective film 900 and the composite black optical film 800, providing the advantage of enhanced sealing properties.

In another embodiment, a different type of display module is provided, as shown in FIG. 6-4. This display module includes a substrate 110 with multiple light-emitting elements 120 arranged on its surface. The substrate 110 is layered with a lower light-transmitting layer 810, above which is a black optical layer 820, and a transparent protective layer 900 is positioned over the black optical layer 820. The lower light-transmitting layer 810 at least covers the areas between the multiple light-emitting elements 120 on the top surface of the substrate 110. In the regions between the light-emitting elements 120, the top surface of the lower light-transmitting layer 810 is positioned lower than the top surfaces of the light-emitting elements 120. The black optical layer 820 covers the top surface of the lower light-transmitting layer 810, and its top surface is no higher than the top surfaces of the light-emitting elements 120. The transparent protective layer 900 covers both the top surface of the black optical layer 820 and the top surfaces of the light-emitting elements 120. The light-emitting elements 120 press against the lower light-transmitting layer 810 and the black optical layer 820, causing these layers to curve upwards around the sides of the light-emitting elements 120, with each light-emitting element 120 penetrating at least through the black optical layer 820. As a result, the black optical layer 820 does not contact the surfaces of the light-emitting elements 120, as the lower light-transmitting layer 810 serves as a barrier between the black optical layer 820 and the surfaces of the light-emitting elements 120.

In these embodiments, the lower light-transmitting layer 810 is positioned directly on the top surface of the substrate 110, covering the areas between adjacent flip-chip light-emitting elements 120, effectively filling the gaps between each light-emitting element 120. This configuration means that the lower light-transmitting layer 810 wraps around each light-emitting element 120 from the sides. Additionally, the top surface of the lower light-transmitting layer 810 is positioned lower than the top surfaces of the light-emitting elements 120, which indicates that only the bottom regions of each light-emitting element 120 are enclosed by the lower light-transmitting layer 810. The upper regions, including portions of the sides and the entire top surface, extend above the lower light-transmitting layer 810. With this structure, the lower light-transmitting layer 810 effectively covers the top surface of the substrate 110. It also avoids issues that could arise from the low flatness of the substrate surface. If the black optical layer 820 were applied directly to the substrate surface, an uneven or incomplete coverage could result if the layer is too thin, or a loss of brightness and display uniformity could occur if the layer is too thick, making the thickness of the black layer difficult to control.

In yet another embodiment of this implementation, as shown in FIG. 6-5, the multiple light-emitting elements 120 include at least one flip-chip LED 6121. To accommodate potential tilting of the flip-chip LED after installation, the design ensures that the height difference between the top surface of the black optical layer 820 and the top surface of the LED chip 6121 is at least equal to ¼ or ½ of the substrate height of the flip-chip LED 6121. Ideally, the top light-emitting surface of the flip-chip LED should be parallel to the top surface of the substrate; however, slight angle deviations may occur during installation, creating a small tilt.

This height difference design allows the top surface of the black optical layer to remain lower than the top surface of the flip-chip LED. Even if the chip is slightly tilted, the light-emitting surface will not be obstructed, ensuring proper light output. Additionally, the thickness of the black optical layer that light needs to penetrate from the sides remains consistent, enhancing the uniformity of the display panel and reducing screen artifacts. In one embodiment, after considering display quality and manufacturing complexity, it is recommended that the height difference between the top surface of the black optical layer 820 and the top surface of the flip-chip LED 6121 be no less than ½ of the substrate height of the flip-chip LED. This not only maintains display quality but also reduces the precision requirements for module processing, thereby improving yield rates.

In some alternative embodiments, to meet varying brightness and black level requirements of the display module, the light transmittance of the black optical layer 820 can be adjusted to different specifications as needed. When aiming to enhance the black level effect of the display module when it is off, the transmittance of the black optical layer 820 can be set between 0-5%, making it nearly opaque to achieve a deeper black appearance. On the other hand, if the objective is to increase the brightness of the display module, the transmittance of the black optical layer 820 can be set between 10%-30%, such as at 20%, to enhance light transmission while retaining a moderate black effect, thereby improving display brightness.

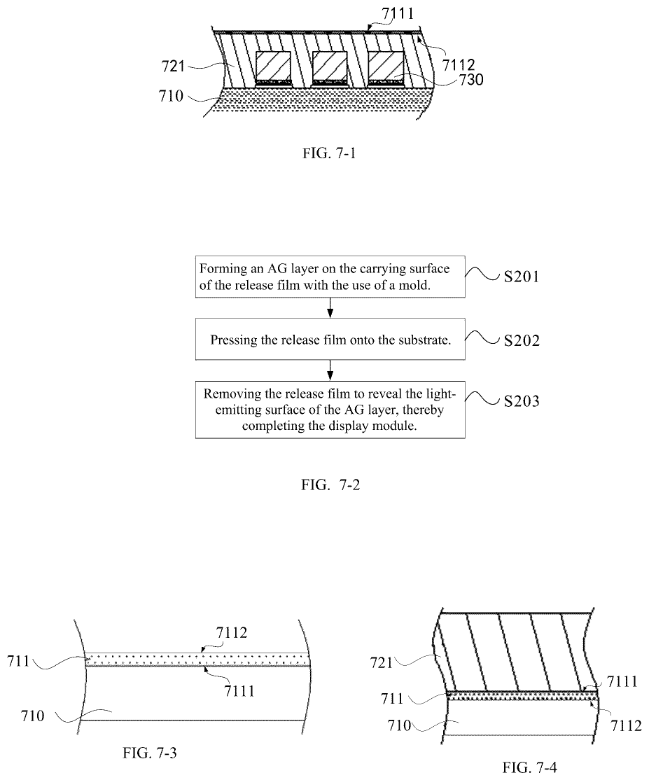

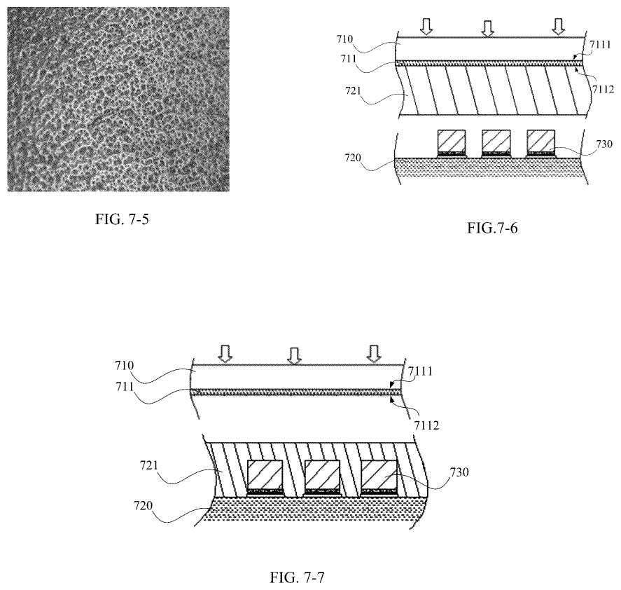

In another embodiment of this implementation, as shown in FIG. 6-6, a transparent protrusion 630 is placed on the top surface of the flip-chip LED 6121 to enhance the light output efficiency of the chip to some extent. In a further embodiment, as shown in FIG. 6-7, a transparent protrusion 640 is also positioned on the top surface of the flip-chip LED 6121, with its central area raised higher than the edges. This transparent protrusion 640, being fully transparent, does not interfere with the light output of the flip-chip LED 6121.

The shape of the transparent protrusion 640, with a high center and low edges, allows the black optical layer 820 to be smoothly compressed beneath the transparent protrusion 640 during the hot lamination process. In this configuration, the black optical layer 820 conforms to the high-center, low-edge shape of the transparent protrusion 640, pressing down smoothly over it and covering the areas between the flip-chip LEDs 6121. This design helps to reduce or even eliminate any black optical layer residue on the top surface of the flip-chip LED, which could otherwise reduce the chip's light output. The transparent protrusion 640 can be formed by hot laminating an original transparent layer onto the substrate surface. During this process, most of the transparent layer is pressed down onto the top surface of the substrate, filling the spaces between the flip-chip LEDs 6121 to form the lower light-transmitting layer 810. The remaining portion of the transparent layer stays on the top surfaces of the flip-chip LEDs 6121, thereby creating the transparent protrusion 640.

In another embodiment, each light-emitting component 120 includes at least two, three, or more than four flip-chip LEDs. As shown in FIG. 6-8, the light-emitting component 120 contains three flip-chip LEDs: a red LED chip 122, a blue LED chip 123, and another blue LED chip 124. These three chips of different colors form one pixel unit. Since the distance between the three chips is very small, the composite black optical film 800 cannot embed itself into the gaps between the chips. Thus, the three chips penetrate the black optical layer 820 as a single unit. However, if the gaps between the chips are large enough, the composite black optical film 800 can also fill the gaps between the chips.

To minimize the impact of the transparent layer on the light output of the flip-chip LED 6121, the transparency of the lower light-transmitting layer 810, the upper light-transmitting layer 810, and the transparent protrusion 640 can be set as high as possible. In some optional embodiments, the transparency of the lower light-transmitting layer 810, the upper light-transmitting layer 810, and the transparent protrusion 640 can be set to greater than 90%. Additionally, silica powder may be added to the lower light-transmitting layer 810, the upper light-transmitting layer 810, and the transparent protrusion 640 to achieve a light diffusion effect, which can further enhance display brightness.

In some optional embodiments, to ensure a tight bond between layers and to enhance the stability of the display module's performance, the lower light-transmitting layer 810, the upper light-transmitting layer 810, and the black optical layer 820 can all be made from airtight adhesive layers. The specific materials used may include epoxy resins, such as, but not limited to, silicone, silicone-modified epoxy resins, acrylic resins, polyethylene resins, and others.

In this embodiment, among the multiple LED chips, the thickness of the black optical layer 820 is minimized, while the thickness of the transparent protective layer 900 is maximized. This design ensures that the LED chips 120 can easily penetrate the black optical layer 820 while achieving better sealing performance. In a preferred embodiment, the thickness of the black optical layer 820 is set between 3 μm to 10 μm.

In this embodiment, to ensure both display quality and effective scaling performance, the black optical layer 820 is designed with minimal thickness between the light-emitting elements, while the transparent protective layer 900 is thicker. This design allows multiple light-emitting elements 120 to penetrate the black optical layer 820 smoothly. Preferably, the thickness of the black optical layer 820 is recommended to be between 3 μm and 10 μm, with a typical setting of 5 μm. As shown in FIG. 6-9, in another embodiment, for optimal display quality, the position of the black optical layer 820 should align with the position of the light-emitting layer 6122 of the flip-chip LED 6121. Specifically, the top surface of the black optical layer 820 should not exceed the top surface of the light-emitting layer 6122. Ideally, the top and bottom surfaces of the black optical layer 820 should correspond to the top and bottom surfaces of the light-emitting layer 6122. However, since the flip-chip LED 6121 may experience slight tilting after being mounted on the substrate 110, it is sufficient for the top and bottom surfaces of the black optical layer 820 to approximately align with those of the light-emitting layer 6122, without requiring exact alignment. Additionally, the thickness of the black optical layer 820 does not need to precisely match the thickness of the light-emitting layer 6122. It can be flexibly adjusted based on factors such as display quality, processing precision, and cost, to meet the specific production requirements of the product.

As shown in FIG. 6-2, this embodiment provides a manufacturing method for a display module, which includes: providing a substrate 110, multiple LED chips 120, a composite black optical film 800, and a transparent protective layer 900. The composite black optical film 800 comprises a black optical layer 820, with an upper light-transmitting layer 830 and a lower light-transmitting layer 810 respectively covering the upper and lower surfaces of the black optical layer 820. The composite black optical film 800 is initially placed onto the substrate 110 and press-fitted, allowing the light-emitting surfaces of the multiple LED chips 120 to pass through the black optical layer 820 of the composite black optical film 800. Subsequently, the transparent protective layer 900 is applied and press-fitted onto the upper surface of the composite black optical film 800, ensuring that the top surface of the transparent protective layer 900 remains flat and smooth.

The black optical layer 820 in the composite black optical film 800 gradually decreases in thickness due to the pressure exerted by the top portions of the LED chips 120, the lower light-transmitting layer 810, and the upper light-transmitting layer 830. As a result, the top portions of the LED chips 120 penetrate through the black optical layer 820, preventing any residual black optical layer 820 from remaining on top of the LED chips 120 and blocking their light-emitting surfaces. This ensures excellent consistency in the light-emitting performance of the LED chips 120 and provides the advantage of simple manufacturing.

In the described manufacturing method, the penetration of the black optical layer 820 by the top portions of the multiple LED chips 120 occurs in two scenarios. In the first scenario, the top portions of the LED chips 120 penetrate through the lower light-transmitting layer 810 first and then through the black optical layer 820. In the second scenario, the top portions of the LED chips 120 press against part of the lower light-transmitting layer 810, penetrating the black optical layer 820 together with it. In both scenarios, the lower light-transmitting layer 810 acts as a barrier, ensuring that the LED chips 120 do not come into direct contact with the black optical layer 820. The mutual pressure between the LED chips 120 and the upper light-transmitting layer 830 causes the top portions of the LED chips 120 to penetrate through the black optical layer 820. As a result, the lower light-transmitting layer 810 and the upper light-transmitting layer 830 meet at the top portions of the LED chips 120, preventing any residual black optical layer 820 from remaining on top portions of the multiple LED chips 120.

In another embodiment of this invention, when the composite black optical film 800 is applied and press-fitted onto the substrate 110, the process is performed under a vacuum and heating environment, combined with applied pressure. This causes the composite black optical film 800 to soften, allowing the light-emitting surfaces of the multiple LED chips 120 to penetrate through the black optical layer 820 under pressure. Under the vacuum environment, the composite black optical film 800 adheres more tightly to the substrate 110. When combined with the heating environment, the composite black optical film 800 softens into a paste-like state, gaining some fluidity. This process helps reduce air bubbles between the composite black optical film 800 and the surface of the substrate 110. Under the applied pressure-for example, on the upper surface of the substrate 110, when pressure is applied to the upper light-transmitting layer 830 of the composite black optical film 800—the top portions of the LED chips 120 push upward against the lower light-transmitting layer 810 and the black optical layer 820. As the black optical layer 820 is compressed, it flows around the periphery of the top portions of the LED chips 120, preventing it from remaining on the top portions of the LED chips 120. This ensures that the light-emitting surfaces of the top portions of the LED chips 120 are not blocked, resulting in consistent light output performance across the LED chips 120.

In the aforementioned steps, the lower light-transmitting layer 810 serves as a buffer and lubricant, allowing the black optical layer 820 to flow more easily toward the periphery of the top portions of the multiple LED chips 120. This ensures that the LED chips 120 penetrate the black optical layer 820 without directly contacting it. In this embodiment, the LED chips 120 do not penetrate the lower light-transmitting layer 810. Instead, the LED chips 120 lift the lower light-transmitting layer 210 as they push through the black optical layer 820, ultimately fusing with the upper light-transmitting layer 830.

In another embodiment, after penetrating the black optical layer 820, the LED chips 120 may also penetrate the lower light-transmitting layer 810, making direct contact. Additionally, parts of the upper light-transmitting layer 830 can move downward, merging with the lower light-transmitting layer 810.

In another embodiment, the lower light-transmitting layer 810 and the upper light-transmitting layer 830 are made of the same material. This allows for a tighter fusion when they come into contact and merge, preventing delamination and ensuring long-term durability without separation over extended use.

In another embodiment, the transparent protective layer 900 is applied and press-fitted onto the upper surface of the composite black optical film 800 under vacuum and heat conditions, with pressure applied. Under the vacuum environment, the black optical layer 820 adheres more closely to the upper surface of the composite black optical film 800. When combined with the heating environment, the transparent protective layer 900 softens into a paste-like state, filling the uneven surfaces on the upper side of the composite black optical film 800. This process reduces air bubbles between the composite black optical film 800 and the transparent protective layer 900. As a result, the final display module features a smooth external surface, providing both protection for the display module and case of cleaning by preventing dust buildup on the surface.

As a further refinement of the manufacturing process, when the composite black optical film 800 is applied and press-fitted onto the substrate 110, the top light-emitting surfaces of the multiple LED chips 120 penetrate through the lower light-transmitting layer 810 and the black optical layer 820 of the composite black optical film 800. However, the LED chips 120 do not penetrate the upper light-transmitting layer 830 of the composite black optical film 800, ensuring that a protective layer remains over the top surfaces of the LED chips 120 at all times.

In this embodiment, to ensure tighter adhesion between the composite black optical film 800 and the substrate 110, the thickness of the composite black optical film 800 should be kept as thin as possible. After the thin composite black optical film 800 is press-fitted onto the substrate 110, the outer surface of the composite black optical film 800 will have an uneven texture due to the protrusion of the LED chips 120 from the substrate 110. Therefore, to allow the transparent protective layer 900 to fully fill the uneven outer surface of the composite black optical film 800, the thickness of the transparent protective layer 900 should be greater than that of the composite black optical film 800.

In this embodiment, to ensure a closer bond between the composite black optical film 800 and the substrate 110, the thickness of the composite black optical film 800 should be minimized. When the thinner composite black optical film 800 is pressed onto the substrate 110, the unevenness of the surface arises due to the protrusion of multiple light-emitting elements 120 from the substrate 110, resulting in a textured outer surface for the composite black optical film 800. To allow the transparent protective film 900 to fully fill the uneven surface of the composite black optical film 800, the thickness of the transparent protective film 900 should be greater than that of the composite black optical film 800. Additionally, to facilitate the penetration of multiple light-emitting elements 120 through the black optical layer 820, the black optical layer 820 within the composite black optical film 800 is designed with minimal thickness.

### Embodiment 6

This embodiment provides a display module, which further includes a composite optical film. The difference from the previous examples lies in the fact that the composite optical film contains an anti-reflective and anti-glare film (AG film). The AG film is adhered to the packaging layer 721 of the display module, effectively reducing external light interference and enhancing the consistency of black display on the display panel.

This embodiment provides a display module, as shown in FIG. 7-1. The display module includes a substrate 720 with LED chips 730 arranged on it, and a packaging layer 721 covering both the substrate 720 and the LED chips 730. The packaging layer 721 fully encloses the LED chips 730 on the substrate 720. Additionally, the display module includes an AG layer 711 press-fitted onto the packaging layer 721, with its light-emitting surface exposed and its light-receiving surface directly attached to the packaging layer 721. In another embodiment, the light-emitting or light-receiving surface of the AG layer 711 can be either a smooth surface or a rough surface. If the light-emitting surface of the AG layer 711 is a rough surface, it contains multiple concave points.

To provide the above display module, please refer to FIG. 7-2. This embodiment provides a manufacturing method for a display module, which includes the following steps:
S201: Form the AG layer 711 on the bearing surface of the release film 710 using a mold. The light-emitting surface 7111 of the formed AG layer 711 adheres to the bearing surface.

S202: Press-fit the packaging layer 721 along with the release film 710 carrying the AG layer 711 onto the substrate 720. After press-fitting, the packaging layer 721 covers the substrate 720 of the substrate 720 and the LED chips 730 on the substrate 720. The AG layer 711 is positioned between the release film 710 and the packaging layer 721, with the light-receiving surface 7112 of the AG layer 711 bonded to the packaging layer 721.
S203: Remove the release film 710, exposing the light-emitting surface 7111 of the AG layer 711, thereby obtaining the display module.

In this embodiment, please refer to FIG. 7-3. To directly bond the AG layer 711 with the packaging layer 721, it is first necessary to form the required AG layer 711 on the release film 710. The so-called AG layer 711 corresponds to the structural layer with anti-reflective and anti-glare properties, typically formed by applying one or more layers of optical materials onto a substrate 720. In the solution provided by the embodiment of the present application, the AG layer 711 is formed on the bearing surface of the release film 710. The release film 710 can then be peeled off during the subsequent process steps, enabling the AG layer 711 to bond directly with the packaging layer 721 in the final display module structure without including any additional substrate layers carrying the AG layer 711.

After the AG layer 711 is formed on the release film 710, it needs to be peeled off in the subsequent process. As the AG layer 711 is carried by the release film 710 during peeling, the surface of the AG layer 711 that does not adhere to the release film 710 directly bonds with the packaging layer 721. Please refer to FIG. 7-4. For the display module, the surface of the AG layer 711 bonded to the packaging layer 721 corresponds to the light-receiving surface 7112, which aligns with the LED chips 730. Meanwhile, the light-emitting surface 7111 of the AG layer 711, which adheres directly to the release film 710, also serves as the light-emitting surface of the display module. Accordingly, the bearing surface of the release film 710 refers to the side of the release film 710 used to carry the AG layer 711 and the surface that directly adheres to the AG layer 711.

After the release film 710 with the AG layer 711 is formed, the release film 710 can be press-fitted with the packaging layer 721. The specific press-fitting process can involve hot lamination, where heat and pressure are applied to combine these two layers into one. During the press-fitting process, the release film 710 itself does not adhere to the packaging layer 721. Instead, the AG layer 711 directly bonds with the packaging layer 721, ensuring that only the AG layer 711 is connected with the packaging layer 721. This facilitates the subsequent peeling of the release film 710 from the AG layer 711, leaving the packaging layer 721 bonded solely with the AG layer 711. This design fundamentally prevents issues such as edge curling. Moreover, since the connection between the AG layer 711 and the packaging layer 721 is achieved through hot lamination, there is no need to apply an additional packaging layer between them. This further reduces the structural layers of the display module. After hot lamination, the bond between the packaging layer 721 and the AG layer 711 is exceptionally tight, significantly lowering the risk of the AG layer 711 peeling off.

Because the AG layer 711 is formed on the release film 710 and directly bonded with the packaging layer 721, it means that the surface of the AG layer 711 not adhered to the release film 710 is bonded to the packaging layer 721. After the press-fitting process, the release film 710 is removed, exposing the AG layer 711 on the surface of the packaging layer 721, which serves as the light-emitting surface of the display module.

The AG layer 711 is formed using a mold, and its specific optical properties are directly related to the structure of the mold. Since the AG layer 711 in this embodiment is formed on the release film 710, once the press-fitting process is completed and the release film 710 is removed, the AG layer 711 is exposed on the surface of the packaging layer 721. Therefore, corresponding patterns can be applied to the bearing surface of the release film 710 to achieve the desired roughness on the light-emitting surface 7111 of the AG layer 711. In other words, in some embodiments, before forming the AG layer 711 on the bearing surface of the release film 710, the bearing surface of the release film 710 can be treated to create a rough surface. Forming the AG layer 711 through a mold inherently means that the light-receiving surface 7112 of the AG layer 711 will be a rough surface. If the bearing surface of the release film 710 is also treated as a rough surface, the light-emitting surface 7111 of the AG layer 711 will exhibit the desired roughness, further enhancing the anti-reflective and anti-glare properties of the AG layer 711.

In addition to its anti-reflective and anti-glare properties, the AG layer 711 can also achieve additional optical processing effects by applying specific patterns on the release film 710. For instance, in some embodiments, the bearing surface of the release film 710 can be treated to create a rough surface by forming multiple bumps or micro-optical structures on it. As the bearing surface of the release film 710 is structured with several bumps (island-like structures), grooves are formed between these bumps. These grooves can be either partially or fully continuous. Correspondingly, the light-emitting surface 7111 of the AG layer 711, when cast from the mold, will feature concave points that match the bumps and also feature vein-like raised structures corresponding to the grooves. When light emitted by the LED chip passes through the AG layer 711, the outgoing light is refracted, reflected, and focused by the vein-like structures. The randomness of these micro-optical structures enhances the light-mixing effect, resulting in reduced color differences across the viewing angles of the display module. This improves the overall display uniformity of the display module.

Please refer to FIG. 7-5, which illustrates a schematic diagram of the surface structure of the AG layer 711 in this embodiment. Several concave points are formed on the light-emitting surface 7111 of the AG layer 711, with raised vein-like structures formed between the concave points. When light emitted from the LED chip passes through the AG layer 711, the outgoing light is refracted, reflected, and focused by the raised vein-like structures, resulting in an enhanced light-mixing effect. This design reduces the color difference across the viewing angles of the display module, thereby improving the overall display uniformity of the display module.

In another embodiment, the AG layer 711 and the packaging layer 721 will ultimately form a display module together with the substrate 720. Please refer to FIG. 7-6, which provides details of the process where the packaging layer 721 and the release film 710 with the AG layer 711 are press-fitted onto the substrate 720. This process can include the following steps:
Step a24: Form the packaging layer 721 on the light-receiving surface 7112 of the AG layer 711.
Step b24: Press-fit the release film 710 with the AG layer 711 and the packaging layer 721 together onto the substrate 720.

This manufacturing process involves first combining the packaging layer 721 with the AG layer 711 before press-fitting it onto the substrate 720. Specifically, the packaging layer 721 is formed on the light-receiving surface 7112 of the AG layer 711. Then, the packaging layer 721, along with the AG layer 711 and the release film 710, is press-fitted onto the substrate 720, creating an integrated packaging structure with the AG layer 711, the packaging layer 721, and the substrate 720. Finally, the release film 710 is removed, resulting in the desired display module, as shown in FIG. 7-1.

In another embodiment, please refer to FIG. 7-7, where the process of press-fitting the packaging layer 721 and the release film 710 with the AG layer 711 onto the substrate 720 may also include:
Step a25: Press-fit the packaging layer 721 onto the substrate 720.
Step b25: Press-fit the release film 710 with the AG layer 711 onto the packaging layer 721.

In this manufacturing method, the packaging layer 721 has been thermally laminated on the substrate 720 in advance to form an integrated packaging structure with the lamp board 720, followed by the precise press-fitting of the release film 710 carrying the AG layer 711 onto the packaging layer 721. Then, the release film 710 is removed, resulting in the desired display module.

In one embodiment, to enhance the anti-reflective and anti-glare properties of the AG layer 711, at least one of the light-emitting surfaces 7111 and the light-receiving surface 7112 is designed as a rough surface. By treating the mold and the release film 710 accordingly, the corresponding surface of the AG layer 711 can be made rough. Specifically, if the mold is configured with a rough surface, the light-receiving surface 7112 of the AG layer 711 can be made rough. Similarly, if the bearing surface of the release film 710 is set to be rough, the light-emitting surface 7111 of the AG layer 711 will have a rough texture. In some optional embodiments, both the light-emitting surface 7111 and the light-receiving surface 7112 can be rough, ensuring maximum anti-reflective and anti-glare performance of the AG layer 711. In certain embodiments, the bearing surface of the release film 710 features multiple bumps, resulting in a corresponding rough light-emitting surface 7111 with multiple concave points. In such cases, the AG layer 711 can focus light emitted from the sides of the LED chips 730, reducing scattered light and minimizing color differences across various side viewing angles.

The display module in this embodiment is manufactured using the display module manufacturing method described in this application. The AG layer 711, press-fitted onto the packaging layer 721, does not contain any substrate or packaging layer, as it directly bonds with the packaging layer 721 through a thermal lamination process.

By press-fitting the AG layer 711 directly onto the packaging layer 721, this display module eliminates the need for traditional AG film substrates and packaging layers, improving the module's structural integrity. This approach reduces the likelihood of the AG layer 711 peeling off, while also preventing issues such as PET curling, weak adhesion, and yellowing.

### Embodiment 7

When an LED chip is soldered onto a substrate, a used tin solder paste becomes silver after being melted and covers a surface of a solder pad, to form a silver surface. For this problem, in the related technology, after the LED chip is soldered, black ink is printed on the silver surface using an ink-jet printing process. However, because a used ink material has extremely low viscosity (good fluidity), an ink climbing phenomenon occurs (that is, the ink climbs toward a side surface of the LED chip) after the ink is printed onto the surface of the substrate and climbs onto an light emitting surface of the LED chip, thereby covering the upper surface of the LED chip, which affects light emission of the LED chip. For this problem, this embodiment provides a display module with a structure, to effectively avoid or as much as possible reduce a case that ink climbs onto the upper surface of the LED chip. In addition, this embodiment may be individually implemented independently of other embodiments.

As shown in FIG. 8-1 to FIG. 8-5, the display module provided in this embodiment includes a substrate 114, and a plurality of light-emitting units 214 arranged on the substrate 114. A light-emitting unit 214 includes at least one LED chip. It should be understood that for the light-emitting units 214 and the substrate 114 in this embodiment, reference may be made to, but not limited to, the foregoing embodiments. Details are not described herein again. The display module further includes an black optical layer 316 arranged between the light-emitting units 214. The black optical layer 316 is formed by ink, and includes a first portion 3161. In this example, the first portion 3161 is a relatively flat part, and in another example. The first portion may alternatively be a concave surface, a convex surface, or a rough surface), and a second portion 3162 connected to the first portion 3161. The second portion 3162 is located around the light-emitting unit 214 and extends from the first portion 3161 toward the top of the light-emitting unit 214 (that is, a side of the light-emitting unit 214 far away from the substrate 114), the second portion 3162 is higher than the first portion 3161, and compared with the first portion 3161, the second portion 3162 is closer to the light-emitting unit 214.

In this embodiment, a packaging layer includes light-transmitting cladding units 317, the light-transmitting cladding units 317 are in a one-to-one correspondence with the light-emitting units 214, and are used for preventing the second portion 3162 from crossing right above the light-emitting units 214, and the light-transmitting cladding unit 317 covers a light emitting surface of the light-emitting unit 214. Specifically, the light-transmitting cladding unit 317 may cover a top out-light surface of an LED chip included in the light-emitting unit 214 (which is a surface of the LED chip far away from the substrate, and may also be referred to as an upper surface of the LED chip). The ink has extremely low viscosity and good fluidity, and therefore is prone to climbing along a side surface of the LED chip. In this embodiment, there is a height difference between the light-transmitting cladding unit 317 and the black optical layer 316 to prevent the ink from climbing. For example, the height of the black optical layer 316 is not greater than the height of the light-transmitting cladding unit 317. Because the light-transmitting cladding unit 317 covers the upper surface of the LED chip, and the top of the black optical layer 316 is lower than the upper surface of the LED chip, the ink can be prevented from climbing to the upper surface of the LED chip during climbing, thereby avoiding masking or partially masking the upper surface of the LED chip (ink climbing phenomenon) from causing light shielding, the practicability is good, and the effect of preventing the ink from climbing is good. In addition, the light-transmitting cladding unit 317 has a long transparent light path, to facilitate reduction of luminance loss of the LED chip. It is only necessary to cover the upper surface of the light-emitting unit 214 with the light-transmitting cladding unit 317 in advance before the black optical layer 316 is arranged, the structure is simple, and the manufacturing costs are low, to facilitate wide application and market promotion.

In some embodiments, the light-transmitting cladding unit 317 includes a front light-transmitting layer 3171 located on an upper surface of the light-emitting unit 214 and a side light-transmitting layer 3172 located on a side surface of the light-emitting unit 214. In some examples, the LED chip may be a face-up chip, the light-transmitting cladding unit 317 may be formed through printing of an ink-jet printing process, a light-transmitting material, but not limited thereto, may be used as a printing material, and ink is sprayed onto the top of the LED chip to form the front light-transmitting layer 3171. The front light-transmitting layer 3171 is arranged adjacent to the black optical layer 316 (as shown in FIG. 8-1 and FIG. 8-2), and the front light-transmitting layer 3171 may be connected to the black optical layer 316 (as shown in FIG. 8-3 and FIG. 8-4). The printing material has fluidity and therefore can flow to a peripheral side of the LED chip to form the side light-transmitting layer 3172, and the side light-transmitting layer 3172 may also be formed through printing of the ink-jet printing technology. In another example, the LED chip may alternatively be a flip chip. The light-transmitting cladding unit 317 may be dome-shaped; and the height of the light-transmitting cladding unit 317 is less than the width of the light-transmitting cladding unit 317, to facilitate material saving. Certainly, the shape of the light-transmitting cladding unit 317 may not be limited, and the top of the light-transmitting cladding unit 317 may be a plane or be in another shape.

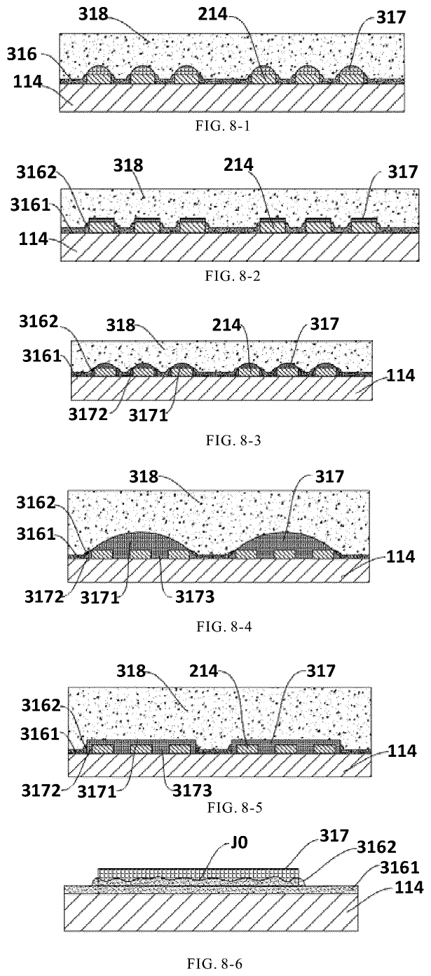

In some embodiments, the second portion 3162 is located under the upper surface of the light-emitting unit 214. For example, as shown in FIG. 8-1 to FIG. 8-5, the top of the black optical layer 316 is lower than the top of the LED chip. For example, when the LED chip is a face-up chip, the top of the black optical layer 316 is lower than the top of the LED chip, to further prevent ink of the black optical layer 316 from flowing to the top out-light surface of the LED chip; and the top of the second portion 3162 is not higher than the upper surface of the light-emitting unit 214, to prevent the upper surface of the light-emitting unit 214 from being blocked by the second portion 3162 and facilitate light emission from the side surface of the LED chip. During actual process implementation, according to a process implementation status, all of the second portion 3162 may not be required to be under the upper surface of the light-emitting unit 214, and requirements can be satisfied as long as a major part (for example, more than 80%) is located under the upper surface of the light-emitting unit 214. In some embodiments, the formed black optical layer 316 is black, and the display module may be used for, but not limited to, a direct view product. For example, the black optical layer 316 may be formed by, but not limited to, black ink through printing of an ink-jet printing device, to improve the contrast. A curved line is formed at a junction of the second portion 3162 and the side surface of the light-emitting unit 214 or a junction JO of the second portion 3162 and the light-transmitting cladding unit 317, as shown in FIG. 8-6. The curved line formed here is an irregular curved line in some examples; and certainly a regular curved line may alternatively be formed in some other examples.

In some application scenarios, the black optical layer 316 is arranged in a scam between two adjacent light-emitting units 214 and on the light-emitting units 214 until the edge of the substrate 114, as shown in FIG. 8-1 and FIG. 8-2. The thickness of the black optical layer 316 ranges from 3 μm to 120 μm. In this embodiment, the thickness of the black optical layer 316 may be controlled by controlling, but not limited to, an adhesive output amount and/or the number of jet printing times of a printing nozzle. For example, in some specific application examples, the thickness of the black optical layer 316 may be set to range from 5 μm to 15 μm, thereby reducing use of the ink material based on ensuring black chrominance.

In some embodiments, the packaging layer of the display module may further include a light-transmitting protection layer 318 arranged on the light-transmitting cladding unit 317 and the black optical layer 316, and the light-transmitting protection layer 318 may be manufactured through, but not limited to, adhesive dispensing, mold-pressing, and printing. The thickness of the light-transmitting protection layer 318 ranges from 200 μm to 400 μm. In some examples, the thickness of the light-transmitting cladding unit 317 ranges from 30 μm to 100 μm. For example, the thickness of the light-transmitting cladding unit 317 may range from 30 μm to 80 μm, and may be specifically, but not limited to, 30 μm, 35 μm, 40 μm, 50 μm, or 70 μm. In specific application, when the display module is applied to a direct view product, as shown in FIG. 8-4 and FIG. 8-5, the light-emitting unit 214 may include, but not limited to, three LED chips that emit red light, blue light, and green light respectively, the light-transmitting cladding unit 317 may include a light-transmitting protection layer 3173 arranged in a seam between adjacent LED chips in the light-emitting unit 214, and the front light-transmitting layer 3171 is connected to the light-transmitting protection layer 3173. The thickness of the light-transmitting cladding unit 317 may be controlled by controlling an adhesive output amount or the number of jet printing times of an ink-jet printing nozzle. In this embodiment, the thickness of the light-transmitting cladding unit 317 is 35 μm.

In some examples, the material of the light-transmitting cladding unit 317 may be, but not limited to, an epoxy resin material or a silicon resin material; and the material of the black optical layer 316 may be, but not limited to, an epoxy resin material or a silicon resin material. In this embodiment, the material of the light-transmitting cladding unit 317 may be the same as the material of the black optical layer 316, to facilitate cost reduction.

In some other examples, the hydrophilicity of the light-transmitting cladding unit 317 is different from the hydrophilicity of the black optical layer 316. For example, the light-transmitting cladding unit 317 may have a hydrophilic factor added to have hydrophilicity, the black optical layer 316 may have a hydrophobic factor added to have hydrophobicity, and a difference between the two in hydrophilicity can be used to further effectively avoid a case that the ink crosses the light-transmitting cladding unit 317 to mask or partially mask the upper surface of the LED chip. In some application scenarios, the hydrophilic factor may be, but not limited to, molecules carrying a polar group (polar molecules), and has large affinity with water, and the hydrophobic factor may be, but not limited to, alkane, grease, fat, and most hydrophobic molecules containing grease (non-polar molecules). The hydrophobic factor and water may repel each other. By setting the light-transmitting cladding unit 317 and the black optical layer 316 to be different in hydrophilicity, when ink climbs to the LED chip and encounters the light-transmitting cladding unit 317 located on the LED chip, the ink and the light-transmitting cladding unit do not dissolve each other and repel each other, to effectively prevent the ink from continuing to climb to the upper surface of the light-emitting unit 214 (ink climbing phenomenon), thereby effectively preventing the ink from masking or partially masking the upper surface of the light-emitting unit 214 to affect light emission of the LED chip, the structure is simple, and the costs are low.

This embodiment further provides a manufacturing method for a display module. The manufacturing method may be used for manufacturing a display module shown in the foregoing examples, and the method includes, but not limited to:
Step a23: provide a substrate 114, and arrange a plurality of light-emitting units 214 on the substrate 114.
Step b23: perform ink-jet printing above each of the light-emitting units 214 to form a light-transmitting cladding unit 317, where the formed light-transmitting cladding unit 317 covers an upper surface of the light-emitting unit 214 (that is, a top out-light surface of the light-emitting unit 214). In some examples, in formed light-transmitting cladding units 317, there is a seam between adjacent light-transmitting cladding units 317, and the seam is in communication with a seam between adjacent light-emitting units 214, to subsequently form an black optical layer 316.
Step c23: perform ink-jet printing (through, but not limited to, printing of an ink-jet printing device) along a seam between the light-emitting units 214 on the substrate 114 to form an black optical layer 316, where the formed black optical layer 316 may be, but not limited to, black, and includes a first portion 3161 and a second portion 3162, the second portion 3162 is connected to the first portion 3161, the second portion 3162 is located around the light-emitting unit 214 and extends from the first portion 3161 toward the top of the light-emitting unit 214, and the light-transmitting cladding unit 317 formed in the previous step can prevent the second portion 3162 from crossing to or flowing to the upper surface of the light-emitting units 214.

Optionally, the manufacturing method for a display module in this embodiment may further include: forming a light-transmitting protection layer 318 above the black optical layer 316 and the light-transmitting cladding unit 317. The process of forming light-transmitting protection layer 318 may be, but not limited to, mold-pressing, printing, or adhesive dispensing, which is not limited herein.

### Embodiment 8

In this embodiment, one light-emitting unit is one pixel unit of the display module, and generally includes a red light LED chip, a green light LED chip, and a blue light LED chip (positions of the red light LED chip and the blue light LED chip are interchangeable) that are sequentially arranged in a row or a column. The red light LED chip, the green light LED chip, and the blue light LED chip may be LED chips whose quantum wells emit red light, green light, and blue light respectively. However, in some other examples, the red light LED chip, the green light LED chip, or the blue light LED chip may alternatively be obtained by converting light in a color emitted by an LED chip through a light conversion layer such as a quantum dot film layer or a fluorescent powder layer. In this arrangement, the green light LED chip is adjacent to both the red light LED chip and the blue light LED chip, but the red light LED chip and the blue light LED chip are spaced apart from each other by the green light LED chip. Therefore, a light mixing effect of the green light and the red light and a light mixing effect of the green light and the blue light are both good, while a light mixing effect of the red light and the blue light is poor. As a result, light emitted by light-emitting units as a whole has chromatic aberration, which affects a whole display effect of the display module. This embodiment provides a display module that can resolve this technical problem. In addition, this embodiment may be individually implemented independently of other embodiments.

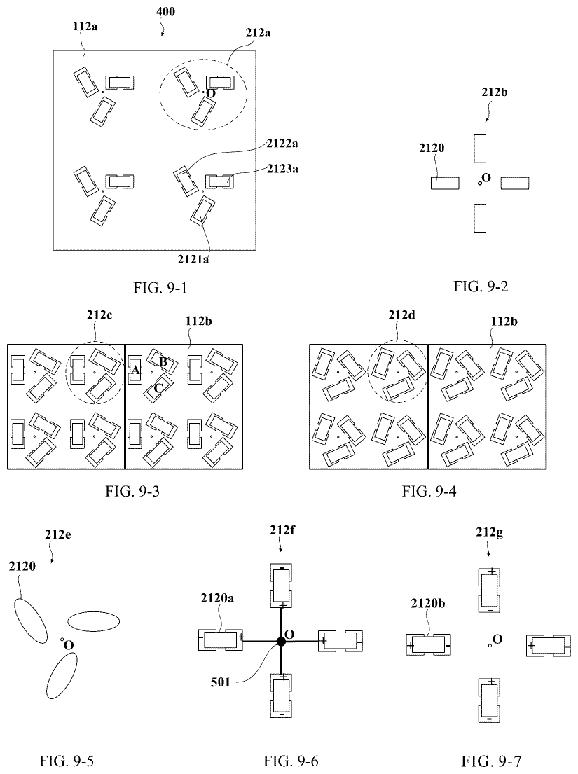

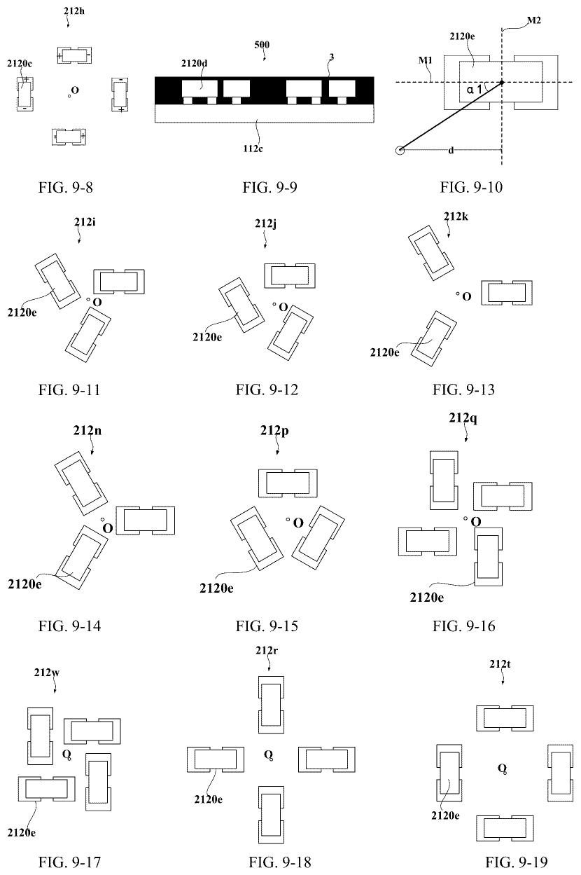

An exemplary display module provided in this embodiment is shown in FIG. 9-1. The display module 400 includes a substrate 112a and a plurality of light-emitting units 212a, and the substrate 112a is provided with a driving circuit.

Each of the light-emitting units 212a includes N LED chips, N is greater than or equal to 3, and colors of the LED chips are not completely the same, that is, may be completely different or partially the same. In other words, each of the light-emitting units 212a includes a plurality of LED chips whose colors are not completely the same. In some examples of this embodiment, each of the light-emitting units 212a includes a red light LED chip 2121a, a green light LED chip 2122a, and a blue light LED chip 2123a, and these LED chips may be chips whose quantum wells emit light in corresponding colors or be chips with light in corresponding colors obtained through conversion of a light conversion layer. In some other examples of this embodiment, colors of LED chips in each of the light-emitting units 212a may not be limited to such three types as red, green, and blue, and may further include, for example, at least one of several colors of a white light LED chip, a yellow light LED chip, and the like. In some examples, the light-emitting unit 212a may include four LED chips in red, green, blue, and white. In some examples, one light-emitting unit 212a is formed by three LED chips such as a red light LED chip 2121a, a green light LED chip 2122a, and a blue light LED chip 2123a. In some other examples, although one light-emitting unit 212a includes LED chips only in three colors such as red, green, and blue, but two or more LED chips are in at least one of the colors.

It may be understood that when one light-emitting unit includes three LED chips, an angle between two adjacent center connection lines is 120°, that is, an angle between a connection line between the center of one LED chip and a rotational symmetry center and a connection line between the center of an adjacent LED chip and the rotational symmetry center is 120°. When one light-emitting unit includes four LED chips, an angle between two adjacent center connection lines is 90°. If the quantity of LED chips in the light-emitting unit is expanded into N, where N is greater than or equal to 3, an angle between a connection line between the center of one LED chip and a rotational symmetry center and a connection line between the center of an adjacent LED chip and the rotational symmetry center is 360°/N.

In this embodiment, for the size and the type of the LED chips, reference may be made to, but not limited to, the foregoing embodiments. In some examples of this embodiment, each LED chip on the substrate 112a is a chip with a flip structure, and the display module 400 is a COB display module, or may be a COG (Chip On Glass) display module.

In this embodiment, the LED chips in each of the light-emitting units 212a are arranged rotationally symmetrically, the so-called rotationally symmetric arrangement means that a pattern formed by arranging the LED chips in each of the light-emitting units 212a is a rotationally symmetric pattern, and the rotationally symmetric pattern is defined as follows: if one planar pattern after being rotated by angle of a (in radian) around one fixed point on a plane coincides with the initial pattern, this pattern is referred to as a rotationally symmetric pattern, this fixed point is referred to as a rotational symmetry center, and the rotating angle is referred to as a rotational angle. Typical rotationally symmetric patterns include a pattern of a fan blade, a pattern of a Hong Kong orchid tree in the regional emblem of the Hong Kong Special Administrative Region, and the like. In the corresponding pattern of each of the light-emitting units 212a in this embodiment, after being rotated by a specific angle around the rotational symmetry center, any LED chip may coincide with another LED chip.

It may be seen from FIG. 9-1 that, in a light-emitting unit 212a, one LED chip is adjacent to two other LED chips in a rotational direction, and the LED chips in the light-emitting unit 212a on one side close to a rotational symmetry center O are all adjacent to each other, thereby resolving the problem in the existing technology in which LED chips are arranged in rows or columns, where some LED chips are adjacent to each other at a short distance, and some LED chips are spaced apart from each other at a long distance, thereby causing an undesired light mixing effect because distances between the LED chips are not balanced. Particularly, in a case that each of the light-emitting units 212a is formed by three LED chips, as shown in FIG. 9-1, the LED chips of the red light LED chip 2121a, the green light LED chip 2122a, and the blue light LED chip 2123a are adjacent to each other in pairs in the rotational direction, and are also adjacent to each other on a side close to the rotational symmetry center, which can significantly improve the light mixing effect of the LED chips in the light-emitting unit 212a and improve the display performance of the display module.

In this embodiment, a vertical projection of an LED chip in a direction parallel to the substrate 112a (denoted as “vertical projection” below) has two symmetry axes perpendicular to each other, and the vertical projection of the LED chip is generally the same as a cross-sectional outline of the LED chip in the direction parallel to the substrate, but this embodiment does not exclude a case that the cross-sectional outline of the LED chip in the direction parallel to the substrate is different from the vertical projection of the LED chip in the direction parallel to the substrate. The vertical projection of the LED chip is, but not limited to, rectangular, rhombic, elliptical, regularly polygonal, or the like.

For case of description, a connection line between the center of the LED chip and the rotational symmetry center is denoted as a “center connection line”. When the vertical projection of the LED chip has a specific length-width ratio (that is, the length-width ratio is greater than 1), a symmetry axis corresponding to a direction in which the vertical projection of the LED chip has a large size is referred to as a “long symmetry axis”, and a symmetry axis corresponding to a direction in which the vertical projection of the LED chip has a small size is referred to as a “short symmetry axis”. In some examples of this embodiment, the center connection line may be parallel to one symmetry axis of the vertical projection of the LED chip. For example, FIG. 9-2 is a schematic diagram of arrangement of LED chips in a light-emitting unit 212b. The light-emitting unit 212b includes four LED chips 2120, and a vertical projection of each of the four LED chips 2120 is in the shape of a rectangle, and has a center connection line that is parallel to a long symmetry axis of the vertical projection, that is, parallel to a long side of the rectangle, and perpendicular to a short symmetry axis, that is, perpendicular to a short side of the rectangle. It may be understood that two electrodes in the LED chip are generally arranged along a symmetry axis of the vertical projection (for example, generally arranged along the long symmetry axis, and certainly this embodiment does not exclude a case of being arranged along the short symmetry axis), so that when the center connection line is parallel to the symmetry axis of the vertical projection, the center connection line coincides with or is perpendicular to a connection line between electrode centers of the two electrodes of the LED chip (briefly referred to as an “electrode center connection line” below). In this way, a die bonding process for LED chips on the substrate is simpler, and the quantity of LED chips in a region with the same area on the substrate is small, which can facilitate heat dissipation of the LED chips and maintain reliability of the LED chips.

In some other examples, the two symmetry axes of the vertical projection of the LED chip are neither parallel to the center connection line, so that a deployment area of the light-emitting unit 212b on the substrate is smaller, to facilitate deployment of more light-emitting units 212b in a limited effective display region on the substrate. In addition, a smaller pitch between the light-emitting units 212b may be achieved, to further reduce a light mixing distance between the LED chips 2120, enhance a light mixing effect of a single light-emitting unit, and improve sharpness of an image displayed by the display module. Still refer to FIG. 9-1. In FIG. 9-1, each LED chip is “I”-shaped. For another example, as shown in FIG. 9-5, a light-emitting units 212e includes three LED chips 2120, a vertical projection of each of the three LED chips is in the shape of an ellipse, and has a center connection line that is parallel to neither a long axis nor a short axis of the ellipse. In some examples of this embodiment, the angle between the center connection line and the electrode center connection line ranges from 25° to 65°. For example, in some examples, it is ensured that the angle between the center connection line and the electrode center connection line ranges from 30° to 60°, and may be, for example not limited to, 30°, 45°, 50°, 55°, or 60°. By limiting the angle range, a contradiction between heat dissipation and light mixing of the LED chips in the light-emitting units may be balanced, to maintain the light mixing effect of the LED chips while ensuring the heat dissipation requirement of the LED chips.

In some examples of this embodiment, a symmetry axis of at least one of the LED chips in one light-emitting unit is parallel to a side edge of the substrate. For example, refer to FIG. 9-3. In FIG. 9-3, a light-emitting unit 212c includes three LED chips A, B, and C. A long symmetry axis of A is parallel to a side edge of a substrate 112b. It may be understood that because a vertical projection of A has a specific length-width ratio, and the long symmetry axis is parallel to the side edge of the substrate 112b, it means that a side of the LED chip A having a large size is parallel to the side edge of the substrate. As a result, when substrates are spliced, an light-emitting amount on a side surface of the LED chip A in the light-emitting unit 212c near a splicing seam is larger. Consequently, chromatic aberration occurs in the light-emitting unit 212c, and the display effect of the display module is affected. Therefore, in some examples of this embodiment, as shown in FIG. 9-4, a vertical projection of an LED chip in a direction parallel to a substrate has two symmetry axes perpendicular to each other, but none of symmetry axes of LED chips in a light-emitting unit 212d is parallel to a side edge of the substrate 112b, to improve a light mixing effect of light-emitting units 212d near a splicing seam, and enhance display performance of the display module.

It may be understood that when the LED chips in the light-emitting units are arranged rotationally symmetrically, the LED chips should not interfere with or contact each other, that is, a specific gap is reserved between adjacent LED chips. In some examples of this embodiment, the LED chip is micron-sized. For example, in some examples, the size of the vertical projection of the LED chip may be as small as 10 μm×10 μm. In some other examples, the size of the vertical projection of the LED chip may reach 400 μm×300 μm. In some examples of this embodiment, a distance from a rotational symmetry center O to each of two symmetry axes of an LED chip is less than 2 mm. In this way, a problem that LED chips in a surface light-emitting unit are arranged excessively dispersedly can be resolved based on ensuring that LED chips do not contact or interfere with each other, which can reduce the deployment area of the light-emitting units, and can also improve the light-emitting effect of the light-emitting units.

In some cases, when the LED chips of the light-emitting unit 212a are arranged rotationally symmetrically, two electrodes of each LED chip are at different distances from the rotational symmetry center O. For example, refer to FIG. 9-6. In a light-emitting unit 212f, each of four LED chips 2120a has one electrode relatively close to a rotational symmetry center O and the other electrode relatively far away from the rotational symmetry center O. In this embodiment, one electrode in the LED chip 2120a close to the rotational symmetry center O is denoted as a “sub-central electrode”, that is, an electrode close to the rotational symmetry center. In some examples of this embodiment, when the LED chips in the light-emitting unit are arranged rotationally symmetrically, polarities of sub-central electrodes of the LED chips may be set to be the same. For example, in FIG. 9-6, the sub-central electrode of each LED chip 2120a is an anode. Optionally, in some examples, the polarities of the sub-central electrodes of the LED chips in the light-emitting units are set to be the same, and these sub-central electrodes are connected together, to implement co-polar driving. For example, in FIG. 9-6, a conducting via hole 501 may be arranged at the rotational symmetry center O, and the sub-central electrodes of the LED chips with the same polarity are connected using the conducting via hole 501.

Certainly, it should be understood that this embodiment is not limited to a case that the conducting via hole 501 needs to be located at the rotational symmetry center O. For example, the conducting via hole may alternatively be located near the rotational symmetry center O. However, relatively, if the conducting via hole 501 is arranged at the rotational symmetry center O, the conducting via hole 501 is at equal distances from all the sub-central electrodes of the LED chips in the light-emitting unit 212f, to facilitate wiring design. In addition, in some other examples of this embodiment, two or more conducting via holes may alternatively be arranged corresponding to one light-emitting unit 212f, and these conducting via holes may be electrically connected together in another manner or be independent of each other. In some other examples, the sub-central electrodes of the LED chips in the light-emitting unit 212f may alternatively be electrically connected in a manner other than using a conducting via, and even in some examples, these sub-central electrodes are not electrically connected together, but are driven independently of each other. Further, in some examples, the polarities of the sub-central electrodes of the LED chips are different. As shown in FIG. 9-7, a light-emitting unit 212g shown in FIG. 9-7 also includes four LED chips 2120b similarly. However, sub-central electrodes of some LED chips 2120b are anodes, and sub-central electrodes of some LED chips 2120b are cathodes. However, in a light-emitting unit 212h shown in FIG. 9-8, two electrodes of an LED chip 2120c are at equal distances from a rotational symmetry center O, and the concept of a sub-central electrode does not exist. In this case, orientations of LED chips 2120c may be set arbitrarily, and polarities of adjacent electrodes of two adjacent LED chips 2120c may alternatively be set to be the same. Refer to FIG. 9-8. For example, in FIG. 9-8, an anode of the top LED chip 2120c is close to an anode of the left LED chip 2120c, a cathode of the top LED chip 2120c is close to a cathode of the right LED chip 2120c, an anode of the right LED chip 2120c is close to an anode of the bottom LED chip 2120c, and a cathode of the bottom LED chip 2120c is close to a cathode of the left LED chip 2120c.

In this embodiment, the plurality of light-emitting units 212a in the display module 400 may be arranged on the substrate 112a in an array, that is, in rows or columns. Still refer to FIG. 9-1. In some examples, orientations of LED chips in different light-emitting units are not associated, and therefore orientations of the light-emitting units are random. However, in some other examples, orientations of LED chips in the same color in the light-emitting unit are the same, as shown in FIG. 9-1. In this way, the LED chips in the same color are arranged easily on a transferred substrate according to the same orientation, and then are transferred together and bonded to the substrate 112a from the transferred substrate in a mass transfer manner, thereby improving the production efficiency of the display module and reducing the production costs.

In some examples of this embodiment, a display module 500 includes a packaging layer 3. The packaging layer 3 may be, but not limited to, the packaging layer structure shown in the foregoing other embodiments. As shown in FIG. 9-9, the packaging layer 3 covers LED chips 2120d. In FIG. 9-9, a case that orientations of LED chips 2120d in a light-emitting unit are different is simply explained. However, a person skilled in the art may understand that orientations of the LED chip 2120d in FIG. 9-9 are not a limitation on orientations of the LED chips 2120d in the display module 500. The packaging layer 3 can fix the LED chips 2120d on a substrate 112c more firmly, to prevent the LED chips 2120d from falling off from the substrate 112c, and can also block intrusion of external moisture into the interior of the LED chips 2120d. Particularly, when the LED chip 2120d includes a quantum dot material, the packaging layer 3 can protect the quantum dot material, improve reliability of the LED chip 2120d, and extend the service life of the display module 500. In some examples, the packaging layer 3 may be a transparent adhesive or a black adhesive. When the packaging layer 3 is a black optical layer or a black adhesive, packaging of the display module 500 may be blackened, to prevent a user from viewing details of the LED chip 2120d and the substrate 112c in the display module 500 from the outside, and improve the display performance of the display module 500.

This embodiment further provides an electronic device. The electronic device includes a processor and at least one display module communicatively connected to the processor. The display module may be a display module provided in any one of the foregoing examples. In the display module, LED chips in a light-emitting units are arranged rotationally symmetrically. It may be understood that the communicative connection between the display module and the processor may be implemented through wired connection, for example, data bus connection, or may be implemented through wireless connection. In addition, in addition to the processor and the display module, the electronic device may further include other devices, for example, at least one of an audio input/output unit, an image acquisition unit, a memory, a Bluetooth module, a Wi-Fi module, and the like.

In the display module and the electronic device provided in this embodiment, because LED chips in a light-emitting unit in the display module are arranged rotationally symmetrically, arrangement of the LED chips in the light-emitting unit is changed, to change the original one-dimensional arrangement between the LED chips into two-dimensional arrangement, thereby reducing a difference between distances between the LED chips, improving balance of light mixing effects between the LED chips in different colors, and enhancing the display effect of the display module.

To enable a person skilled in the art to understand structures and advantages of the display module and the electronic device provided in the foregoing embodiments more clearly, the arrangement solution of the LED chips in the light-emitting unit in the foregoing example continues to be described with reference to examples in this embodiment: it may be understood that the arrangement solution of the LED chips in the light-emitting unit is related to each of the quantity of LED chips in the light-emitting unit, the shape of the LED chip itself, a distance of the LED chip relative to the rotational symmetry center, and an inclination angle of the LED chip relative to a reference direction on the substrate (for example, a direction parallel to a long side or short side of the substrate). In this embodiment, it is assumed that the light-emitting unit has three LED chips, and the vertical projection of the LED chip is “I”-shaped. In this case, specific arrangement of the LED chips in the light-emitting unit depends on the distance between the LED chip and the rotational symmetry center and the inclination angle of the LED chip relative to the reference direction.

First, refer to FIG. 9-10: a size of a vertical projection of an LED chip 2120e in a direction of one symmetry axis is greater than a size of the vertical projection in a direction of the other symmetry axis, and a size of the vertical projection thereof in a direction of a first symmetry axis M1 is greater than that in a direction of a second symmetry axis M2. For case of description, in this embodiment, similarly, a symmetry axis corresponding to a direction in which the vertical projection of the LED chip has a large size is referred to as a “long symmetry axis”, and a symmetry axis corresponding to a direction in which the vertical projection of the LED chip has a small size is referred to as a “short symmetry axis”. Therefore, in FIG. 9-10, the first symmetry axis M1 is the long symmetry axis, and the second symmetry axis M2 is the short symmetry axis. Certainly, in some other examples, if the vertical projection of the LED chip is in the shape of a rectangle, the long symmetry axis is parallel to a long side of the LED chip, and the short symmetry axis is parallel to a short side of the LED chip; if the vertical projection of the LED chip is in the shape of a rhombus, the long symmetry axis is a long diagonal of the rhombus, and the short symmetry axis is a short diagonal of the rhombus; and if the vertical projection of the LED chip is in the shape of an ellipse, the long symmetry axis is a long axis of the ellipse, and the short symmetry axis is a short axis of the ellipse.

In this embodiment, a distance of the rotational symmetry center O from a short symmetry axis 802 of the LED chip 2120e is denoted as an adjustable distance d, and an angle between a connection line between the center of the LED chip 2120e and the rotational symmetry center O, that is, a center connection line, and a long symmetry axis 801 is denoted as an adjustable angle α1. It may be understood that by adjusting values of the adjustable distance d (micron-sized, but in the accompanying drawing, the size of the LED chip 2120e and the size between the LED chips 2120e are both scaled up) and the adjustable angle α1, light-emitting units in which three LED chips 2120e are arranged differently may be obtained. FIG. 9-11 shows a light-emitting unit 212i obtained when the adjustable distance d is 85.75 and the adjustable angle α1 is 29.76°; FIG. 9-12 shows a light-emitting unit 212j obtained when the adjustable distance d is 35.74 and the adjustable angle α1 is 60.66°; FIG. 9-13 shows a light-emitting unit 212k obtained when the adjustable distance d is 126.79 and the adjustable angle α1 is 0; FIG. 9-14 shows a light-emitting unit 212n obtained when the adjustable distance d is 99.96 and the adjustable angle α1 is 0; FIG. 9-15 shows a light-emitting unit 212p obtained when the adjustable distance d is 0 and the adjustable angle α1 is 90°. In each light-emitting unit including three LED chips 2120e and shown in this embodiment, the adjustable distance d is less than 2 mm.

A case that a light-emitting unit includes four LED chips 2120e is described below: FIG. 9-16 shows a light-emitting unit 212q corresponding to an adjustable distance d of 85.75 and an adjustable angle α1 of 30°; FIG. 9-17 shows a light-emitting unit 212w obtained when the adjustable distance d is 47.56 and the adjustable angle α1 is 60°; FIG. 9-18 shows a light-emitting unit 212r obtained when the adjustable distance d is 166.77 and the adjustable angle α1 is 0; FIG. 9-19 shows a light-emitting unit 212t obtained when the adjustable distance d is 0 and the adjustable angle α1 is 0.

Undoubtedly, if a distance of the rotational symmetry center O from the first symmetry axis M1 of the LED chip 2120e is alternatively used as an adjustable distance, light-emitting units in different arrangement situations may be similarly obtained. Alternatively, it is feasible to use an angle between the center connection line and the second symmetry axis M2 as an adjustable angle.

In the display module or the electronic device obtained based on the arrangement solution of LED chips in this embodiment, in a range of a single light-emitting unit, LED chips are all adjacent to each other, thereby optimizing a color mixing effect of various colors and improving the display effect of the display module and the electronic device.

It should be understood that the foregoing embodiments of the present invention may be each independently implemented, or may be combined and implemented according to some of the embodiments or some technical features in the embodiments. In addition, the application of the present invention is not limited to the foregoing examples. A person of ordinary skill in the art may make improvements or modifications according to the foregoing description, and all of the improvements and modifications should all fall within the protection scope of the attached claims of the present invention.

What is claimed is:

1. An LED display module, comprising:
a substrate;
a plurality of LED chips disposed on the top surface of the substrate and electrically connected to the substrate;
a transparent layer arranged on the top surface of the substrate, covering the light-emitting surfaces of the plurality of LED chips; and
a black optical layer disposed on the transparent layer, covering the gaps between the plurality of LED chips.

2. The LED display module according to claim 1, wherein the top surface of the black optical layer is lower than the light-emitting surfaces of the plurality of LED chips, and the black optical layer extends upward to wrap around the sides of the LED chips.

3. The LED display module according to claim 1, wherein the black optical layer does not cover the light-emitting surfaces of the plurality of LED chips and does not contact the plurality of LED chips.

4. The LED display module according to claim 1, further comprising a light transmitting layer disposed on the black optical layer and covering the plurality of LED chips.

5. The LED display module according to claim 4, wherein the black optical layer partially covers the light-emitting surfaces of the plurality of LED chips, and the thickness of the black optical layer on the light-emitting surfaces of the LED chips is less than the thickness of the black optical layer in the gaps between the LED chips.

6. The LED display module according to claim 5, wherein the transmittance of the black optical layer on the light-emitting surfaces of the LED chips is greater than or equal to 40%.

7. The LED display module according to claim 1, wherein each of the plurality of LED chips comprises multiple LED chips, including at least one of red, green, blue, or white LED chips.

8. An LED display module, comprising:
a substrate;
a plurality of LED chips disposed on the substrate;
a composite black optical layer disposed on the substrate and cover the plurality of LED chips, wherein the composite black optical layer includes a lower light-transmitting layer, a black optical layer and an upper light-transmitting layer, and the lower light-transmitting layer and the upper light-transmitting layer are arranged on the bottom and top surfaces of the black optical layer respectively; and
a transparent protective layer arranged above the composite black optical layer;
wherein the lower light-transmitting layer and the black optical layer at least cover the areas between the plurality of LED chips on the top surface of the substrate, and in the regions between the plurality of LED chips, the top surface of the lower light-transmitting layer and the black optical layer are lower than the top surfaces of the plurality of LED chips;
wherein the lower light-transmitting layer and the black optical layer extend upward along the sides of the plurality of LED chips, and the black optical layer does not cover the light-emitting surfaces of the plurality of LED chips, nor does the black optical layer come into contact with the plurality of LED chips.

9. The LED display module according to claim 8, wherein the plurality of LED chips include at least one flip-chip LED, and the height difference between the top surface of the black optical layer and the top surface of the flip-chip LED is greater than or equal to ¼ or ½ of the flip-chip LED substrate height.

10. The LED display module according to claim 8, wherein the light transmittance of the black optical layer is 0-5% or 10%-30%.

11. The LED display module according to claim 8, wherein the surface of the black optical layer is a rough surface containing multiple concaves.

12. A method for manufacturing a display module, comprising:
providing a substrate;
disposing a plurality of LED chips on the top surface of the substrate;
providing a composite black optical layer, which includes a lower light-transmitting layer, a black optical layer and an upper light-transmitting layer, and the lower light-transmitting layer and the upper light-transmitting layer are arranged on the bottom and top surfaces of the black optical layer respectively;
placing the lower light-transmitting layer of the composite black optical layer facing the plurality of LED chips on the substrate and the plurality of LED chips;
using hot pressing on the upper light-transmitting layer to bond the composite optical layer onto the substrate, enabling the light-emitting surfaces of the plurality of LED chips to pass through the black optical layer within the composite black optical layer; and
providing a transparent protective layer on the composite black optical layer, and using hot-pressing process on the transparent protective layer to fitting on the composite black optical layer and the surface of the transparent protective layer is flat.

13. The method for manufacturing a display module according to claim 12, wherein hot-pressing process is pressed under vacuum and heating conditions.

14. The method for manufacturing a display module according to claim 12, wherein the transparent protective film and the upper light-transmitting layer of the composite black optical film are made of the same material.

15. The method for manufacturing a display module according to claim 12, wherein the surface of the black optical layer is a rough surface containing multiple concaves.

16. The method for manufacturing a display module according to claim 12, wherein the after using hot pressing on the upper light-transmitting layer to bond the composite optical layer onto the substrate, the upper light-transmitting layer cover on the light-emitting surfaces of the plurality of LED chips.

17. A method for manufacturing a display module, comprising:
providing a substrate;
disposing a plurality of LED chips on the top surface of the substrate, with a first gap between adjacent LED chips, wherein each of the plurality of LED chips comprises multiple LED chips;
providing a composite layer, which is formed by stacking a transparent layer and a black optical layer;
pressing the composite layer onto the top surface of the substrate, wherein the black optical layer of the composite layer positioned on the transparent layer and away from the light-emitting surfaces of the LED chips; and
applying a light-transmitting layer over the composite layer.

18. The method for manufacturing a display module according to claim 17, further comprising:
removing the black optical layer above the light-emitting surfaces of the plurality of LED chips.

19. The method for manufacturing a display module according to claim 17, wherein the black optical layer does not cover the light-emitting surfaces of the plurality of LED chips.

20. The method for manufacturing a display module according to claim 17, wherein the method of pressing the transparent layer and the black optical layer includes a hot-pressing process.
